(19) United States
(12) Patent Application Publication
(10) Pub. No.: US 2012/0112830 A1
(43) Pub. Date: May 10, 2012

(54) TOWARDS THE VERY SMALLEST ELECTRONIC CIRCUITS AND SYSTEMS: TRANSDUCTION, SIGNAL PROCESSING, AND DIGITAL LOGIC IN MOLECULAR FUSED-RINGS VIA MESH RING-CURRENTS

(76) Inventor: Lester F. Ludwig, Belomont, CA (US)

(21) Appl. No.: 12/940,042

(22) Filed: Nov. 4, 2010

(51) Int. Cl. H03K 17/51

(52) U.S. Cl. 327/603

(57) ABSTRACT

A system implementing molecular electronics is disclosed. The system includes a fused-ring molecule and a molecular orbital structure capable of supporting an induced or sustained ring current. The ring currents can be induced by a time-varying magnetic field, a circularly poralized short duration laser pulse, or other ringcurrent simulating phenomena. At least one aspect of the molecule affecting the ring current can be changed by one or more input stimulus signals. At least one aspect of the ring currents induces an associated output effect responsive to changes in the ring currents. At least one of the ring currents is induced by one or more one time-varying magnetic field, and the mutual interaction among ring currents is used to create electron flows of a mesh-topology electrical circuit.

### CROSS-REFERENCE TO RELATED APPLICATIONS

This application claims benefit of priority of U.S. provisional application Ser. No. 61/239,426 filed on Sep. 2, 2009, incorporated herein by reference.

### BACKGROUND OF THE INVENTION

1. Field of the Invention

The invention pertains to the fields of molecular electronics and chemionics, and in particular to small-scale molecular electronics comprised by interacting ring current flows within and associated with fused-ring molecules. An argument can be made that these is approaching the smallest scale in which electrical-current based electronics can be implemented.

2. Background of the Invention

Since the invention of the transistor, traditional active electronics for signal processing and digital logic has long employed lattice or other spatially repetitive substrate structures—such as crystal lattices, organic polymers, grapheme (sheets and nanotubes)—to provide a framework for creating active devices such as transistors. There are exciting and admirable ongoing efforts to miniaturize active elements using such substrate structures (for example, silicon) to 100's to 10's of nanometers in scale. This includes, inter alia, carbon nanotube FETs and Intel's 45 nm process (“400 transistors on a red blood cell” http://www.podtech.net/home/1904/intels-45-nanometer-process-300-transistors-on-a-red-blood-cell). Although DNA, other molecular recognition processes, and other forms of self-assembly hold much promise for 3D nanoscale assembly, at the time of this filing fabrication approaches still involve and require rendering in a largely planar implementation.

The many special properties of silicon crystals, carbon (and other material) nanotubes, and organic polymers permit some interactions with photonic processes, to a lesser extent magnetic processes, and to a limited extent chemical processes. Grapheme sheets, nanotubes, and organic polymers have already demonstrated a vast number intriguing exotic processes and properties. However, the themes of adapting these processes and properties to signal processing and digital logic applications is essentially one of emulating the familiar processes and devices stemming from well-established traditions of silicon-based electronics.

In many aspects of chemionics, devices such as molecular switches and molecular-scale sensors have been devised. However, these involve electrical currents from elsewhere and often themselves can require a large molecule for even an extremely basic or simple function.

Each of the steps from traditional silicon to (1) small-scale silicon or organic polymers, then scaled down further to (2) grapheme sheets nanotubes, and then potentially scaled down further to (3) established large-molecule molecular switches and sensors devised by contemporary chemionics one way or another still involve a large number of atoms to perform simple tasks.

The present invention moves towards likely the ultimate size reduction for molecular electronic circuits: use of the mutual interaction among ring currents in a fused-ring molecule to create an electrical structure similar to a mesh-topology electrical circuit. Various aspects of molecular structure, conformation, functional groups, rearrangements, etc. are used as input, output, and signal processing processes and elements.

In addition to the reduction in size, the approach and various aspects of the present invention provide a number of additional benefits, opportunities, and applications:
A natural environment for signal transduction on a small-molecule scale;
Interworking with electrical, optical, photonic, excited state, chemical, magnetic, and biological processes and phenomena;
Gateway access to quantum effects and biological operation.
   FIG. 1 depicts a high-level summary of some of these aspects of the invention.

In biology, other processes have evolved with spectacular success. A major component in both metabolism and nervous system function is “signal transduction” (i.e., enzyme cascades, ion channels, etc.). Additionally, other aspects of the nervous system employ supramolecular electrical processes. These biological processes interface with a wide range of chemical, electrical, and photonic processes and implement complex control and signal processing functions within biological organisms. The present invention provides new avenues for access to such biological processes due to its small scale as well as adjacency to an inherent chemical processes, many or all of which can be implemented via organic compounds.

Additionally, experimental and proposed quantum computation systems provide paradigm-changing promise and interesting new capabilities such as “Q-bits” with complex-number-valued states, memory size exponentially larger than physical size, simultaneously superimposed computations, etc. Although this work is astonishing and impressive, quantum computation technologies remain largely theoretical and far from inexpensively manufactured implementation. Part of the problem is accessing the quantum computation phenomena for signal input and output purposes on a very small scale. The present invention provides new avenues for access to quantum effects due to its small scale as well as adjacency to an inherent internal quantum processes.

The ring-current electronics provided by the invention is in one approach driven by a time-varying magnetic field or circularly polarized laser. These can serve as power source, signal input, or both, and can be applied from various directions (for example, in orthogonal orientations) so as to support one, two, or three independent sources. In the cases of laser, a number of selective capabilities can be added. In that the time-varying magnetic field or circularly polarized laser is used as a power source, the resulting powering can be regarded as being similar to a pulsed electrical circuit, AC-powered circuit, clocked logic circuit, etc.

### SUMMARY OF THE INVENTION

With full respect of the aforementioned magnificent systems, methods, and creations, this patent application respectfully submits a new framework for molecular-scale signal processing and digital logic.

In one approach, the mutual interaction among ring currents in a fused-ring molecule is used to create an electrical structure similar to a mesh-topology electrical circuit involving ring currents of dislocated electrons of the π-cloud, associated lone pairs, or other types of electrons or electron arrangements.

The new framework and associated technology uses properties of one or more topologically-cyclic chemical moieties or other cyclic structures to influence affairs at one or more of at least another cyclic moiety or other cyclic structure. In one approach, each of these cyclic moieties or other cyclic structures are within a common molecule. In one approach, some of these cyclic moieties or other cyclic structures are comprised by one molecule while others are comprised by another molecule.

At least one of the cyclic moieties or other structures is used to receive one or more signal inputs (photonic, chemical, magnetic, electrical, etc.), and at least one of the cyclic moieties or other structures is used to provide one or more signal outputs (photonic, chemical, magnetic, electrical, etc.).

Outputs can be rendered as inter-molecular coupling, non-proximal measurements, chemical reactions, molecular rearrangement, signal transduction, change in optical properties, excited state, optical emission, etc.

The new framework and associated invention has many attractive properties and possibilities, including the following:

It does not require lattice or other spatially repetitive substrate structures but rather uses intramolecular interactions within (selected classes of) a cyclic or fused-ring molecule as the substrate;
It does not require lattice or other spatially repetitive substrate structures but rather uses intramolecular interactions within (selected classes of) a cyclic or fused-ring molecule as the substrate;
It can readily support interactions with electrical, photonic, chemical, and magnetic phenomena, allowing for a wide pallet of facilities for signal input, signal output, and system-internal transduction;
Accordingly, it can readily combine molecular electronics with not only photophysics but also photochemistry in various contexts (chromophore, other molecular rearrangement, etc.);
It can provide access to quantum phenomena;
Accordingly, it can combine be used to access types of quantum logic, and further to intermingle traditional Boolean logic and various forms of quantum logic;
It can be integrated into macromolecules such as proteins;
It can be integrated into biological cells;
It can be spatially architected into various 3-dimensional shapes, which in turn can be used as functional elements;
It can leverage familiar electrical circuitry formalisms such as mesh currents, modular interfaces, and subsystem isolation;
It can be realized at least through use of simple organic and heterocyclic chemistry, specifically involving well-known moieties and functional groups.

Study and refinement perhaps may lead to new understandings of processes within living organisms and complex physical materials that are not yet recognized or appreciated.

Other variations are also possible and are provided for by the invention.

### Ring Current Aspects of the Invention

In one aspect of the invention, a molecular electronics arrangement comprises at least one fused-ring molecule capable of supporting an induced ring current of electrons associated with the molecule.

In one aspect of the invention, a molecular electronics arrangement comprises at least one fused-ring molecule capable of sustaining an induced ring current associated with the molecule.

In another aspect of the invention, a fused-ring molecule comprises a fused-ring (“condensed ring”) cyclic structure and a plurality of ring currents of electrons associated with the molecule.

In another aspect of the invention, a fused-ring molecule comprises a fused-ring cyclic structure and disjoint aromatic sextet structures comprised by a fused-ring cyclic molecular are employed.

In another aspect of the invention, at least one ring current is transported by π-electrons.

In another aspect of the invention, at least one ring current transported by π-electrons flows only on one side of a ring plane.

In another aspect of the invention, at least one ring current flows outside a ring plane of the fused-ring molecule.

In another aspect of the invention, at least one ring current flows within a ring plane defined by a ring-shaped interbonded collection of atoms comprised by the fused-ring molecule.

In another aspect of the invention, at least one diatropic (a.k.a. “diamagnetic”) ring current is employed within the fused-ring molecule.

In another aspect of the invention, at least one paratropic ring current is employed within the fused-ring molecule.

In another aspect of the invention, the fused-ring molecule comprises a strained unconjugated ring which as a result of the strain sustains a ring current (“strained ring current”).

In another aspect of the invention, the fused-ring molecule comprises a strained saturated ring which as a result of the strain sustains a ring current (“strained ring current”).

In another aspect of the invention, at least one ring current flows within an atom comprised by the fused-ring molecule.

In another aspect of the invention, at least one ring current is split at a moiety comprised by the fused-ring molecule.

In another aspect of the invention, a magnetic shielding effect within the fused-ring molecule is employed in determining or influencing a ring current.

In another aspect of the invention, a magnetic deshielding effect within the fused-ring molecule is employed in determining or influencing a ring current.

In another aspect of the invention, the magnetic deshielding effect within the fused-ring molecule is created by steric interactions among crowded protons.

In another aspect of the invention, a polar effect within the fused-ring molecule is employed in determining or influencing a ring current.

In another aspect of the invention, the fused-ring molecule comprises a closed 3-dimensional form topologically embeddable in the surface of a torus and a surface current (for example, “sphere current”) is used.

In another aspect of the invention, the fused-ring molecule comprises a closed 3-dimensional form topologically embeddable in the surface of a sphere and a surface current (for example, “sphere current”) is used.

In another aspect of the invention, the fused-ring molecule comprises at least one cyclic structure in a first plane and at least one other cyclic structure in a second plane orthogonal to the first plane.

In another aspect of the invention, the fused-ring molecule comprises at least one aromatic system in a first plane and at least one other aromatic system in a second plane orthogonal to the first plane.

In another aspect of the invention, the fused-ring molecule comprises multiple aromaticity systems from the collection of the n-bond system, σ-bond system, and/or δ-bond system.

### Magnetic Field Aspects of the Invention

In another aspect of the invention, ring currents are induced by at least one time-varying magnetic field.

In another aspect of the invention, ring currents are induced by at least two spatially-orthogonal time-varying magnetic fields.

In another aspect of the invention, at least one time-varying magnetic field is employed as a power source.

### Circularly-Polarized Laser Pulse Aspects of the Invention

In another aspect of the invention, ring currents are induced by at least one circularly-polarized laser pulse.

In another aspect of the invention, ring currents are induced by at least two spatially-orthogonal circularly-polarized laser pulse.

In another aspect of the invention, at least one circularly-polarized laser pulse is employed as a power source.

### Signal Input Aspects of the Invention

In an aspect of the invention, a ring current within a fused-ring molecule is affected by an electrical phenomena signal input process.

In another aspect of the invention, a ring current within a fused-ring molecule is affected by a photonic phenomena signal input process.

In another aspect of the invention, a ring structure within a fused-ring molecule is affected by a photonic phenomena signal input process.

In another aspect of the invention, photochromic compounds are used as transducer elements within fused-ring molecular electronic systems employing operation on and by molecular ring currents.

In another aspect of the invention, a ring current within a fused-ring molecule is affected by a chemical phenomena signal input process.

In another aspect of the invention, a ring current within a fused-ring molecule is affected by a magnetic phenomena signal input process.

In another aspect of the invention, a ring current within a fused-ring molecule is turned on and off by photo-induced molecular rearrangement.

### Signal Output Aspects of the Invention

In an aspect of the invention, a ring current within a fused-ring molecule affects a photonic phenomena signal output process.

In another aspect of the invention, a ring current within a fused-ring molecule affects an optical property which may be used as part of a signal output process.

In another aspect of the invention, a ring current within a fused-ring molecule affects an electrical phenomena signal output process.

In another aspect of the invention, a ring current within a fused-ring molecule affects an electrical property which may be used as part of a signal output process.

In another aspect of the invention, a ring current within a fused-ring molecule affects a chemical phenomena signal output process.

In another aspect of the invention, a ring current within a fused-ring molecule affects a chemical property which may be used as part of a signal output process.

In another aspect of the invention, a ring current within a fused-ring molecule affects a magnetic phenomena signal output process.

In another aspect of the invention, a ring current within a fused-ring molecule affects a magnetic property which may be used as part of a signal output process.

### Signal Processing Aspects of the Invention

In an aspect of the invention, a fused-ring molecule can perform a signal processing operation such as (but not limited to) amplification, threshold detection, comparator functions, nonlinear operations, hysteresis, etc.

In another aspect of the invention, a polymer of fused-ring compounds act together to approximate a distributed-parameter component.

In another aspect of the invention, a polymer of fused-ring compounds act together to approximate a passive distributed-parameter component.

In another aspect of the invention, a polymer of fused-ring compounds act together to approximate an active distributed-parameter component.

In another aspect of the invention, quantum phenomena associated with a fused-ring molecule may be utilized as part of the signal processing operation performed by the fused-ring molecule.

### Logic Operation Aspects of the Invention

In another aspect of the invention, a fused-ring molecule can perform Boolean logic-gate operation such as (but not limited to) AND, OR, INVERT, NAND, NOR, etc.

In another aspect of the invention, ring currents are used to provide access to quantum phenomena that can be used to access types of quantum logic processes.

In another aspect of the invention, traditional Boolean logic is combined with quantum logic.

In another aspect of the invention, quantum phenomena associated with a fused-ring molecule may be utilized as part of the digital logic operation performed by the fused-ring molecule.

### Memory Operation Aspects of the Invention

In an aspect of the invention, a fused-ring molecule can perform a memory function.

In another aspect of the invention, the invention provides for the use photochromic compounds as memory elements within fused-ring molecular electronic systems employing operation on and by molecular ring currents.

In another aspect of the invention, the invention provides for the use photochromic compounds as R-S flip-flop elements within fused-ring molecular electronic systems employing operation on and by molecular ring currents.

### Chemical Reaction Aspects of the Invention

In an aspect of the invention, molecular electronics is combined with photochemistry.

In another aspect of the invention, molecular electronics is combined with molecular rearrangement chemistry.

In another aspect of the invention, molecular electronics is combined with chromophore chemistry.

In another aspect of the invention, molecular electronics is combined with host-guest-chemistry.

### Molecular Structure Aspects of the Invention

In an aspect of the invention, a fused-ring molecule comprises a fused-ring cyclic structure.

In another aspect of the invention, a fused-ring molecule comprises a conjugated compound, ring, moiety, or functional group.

In another aspect of the invention, a fused-ring molecule comprises a hyperconjugated compound, ring, moiety, or functional group.

In another aspect of the invention, a fused-ring molecule comprises a strained ring, moiety, or functional group.

In another aspect of the invention, a fused-ring molecule comprises a bridge.

In another aspect of the invention, a fused-ring molecule comprises a polyvalent bridge.

In another aspect of the invention, a fused-ring molecule comprises a bridged aromatic compound.

In another aspect of the invention, a fused-ring molecule comprises an inorganic ring structure, for example comprising one or more atoms of sulfur, phosphorus, boron, etc.

In another aspect of the invention, a fused-ring molecule is non-planar.

In another aspect of the invention, a fused-ring molecule comprises at least one cluster structure.

In another aspect of the invention, a fused-ring molecule comprises an inorganic cluster structure, for example comprising one or more atoms of sulfur, phosphorus, boron, etc.

In another aspect of the invention, a fused-ring molecule comprises at least one cage structure.

In another aspect of the invention, a fused-ring molecule comprises am inorganic cage structure, for example comprising one or more atoms of sulfur, phosphorus, boron, etc.

In another aspect of the invention, a fused-ring molecule comprises a macrocyclic structure.

In another aspect of the invention, a fused-ring molecule comprises a multidentate macrocyclic structure.

In another aspect of the invention, a fused-ring molecule comprises a cyclophane.

In another aspect of the invention, magnetic coupling is used in conjunction with a cyclophane structure.

In another aspect of the invention, a fused-ring molecule comprises a calixarene.

In another aspect of the invention, a host-guest interaction is used in conjunction with a calixarene structure.

In another aspect of the invention, a fused-ring molecule comprises a nested cyclic macroscopic structure such as that of circulene of sulflower.

In another aspect of the invention, a fused-ring molecule comprises a geodesic polyarene structure such as circulene of sulflower.

In another aspect of the invention, a fused-ring molecule comprises a helicene.

In another aspect of the invention, the spectral or optical properties of a helicene are used.

In another aspect of the invention, a fused-ring molecule comprises an propellane.

In another aspect of the invention, a fused-ring molecule comprises a macrocyclic structure such as but not limited to crown ethers, crown esters, aza-crowns, thia-crowns, selena-crowns, organosilicon crowns, mixed amine-ether crowns, etc.

In another aspect of the invention, a fused-ring molecule comprises a macrocyclic structure such as a phthalocyanine structure, porphyrin structure, cyclic polypyrrole structure, etc.

In another aspect of the invention, a fused-ring molecule comprises an enlarged porphyrin.

### Polycyclic Aromatic Compound Aspects of the Invention

In an aspect of the invention, at least one fused-ring cyclic structure comprises at least one Polycyclic Aromatic Compound (PAC).

In an aspect of the invention, at least one fused-ring cyclic structure comprises at least one Polycyclic Aromatic Hydrocarbon (PAH).

### Heterocyclic Aspects of the Invention

In an aspect of the invention, at least one fused cyclic structure includes at least one heteroatom (non-carbon atom) in at least one ring.

In another aspect of the invention, a fused-ring molecule or fused-ring cyclic structure comprises a fused-ring heterocyclic moiety.

In another aspect of the invention, a fused-ring molecule or fused-ring cyclic structure comprises at least one bridgehead heteroatom.

In another aspect of the invention, at least one fused-ring cyclic structure comprises at least one polycyclic aromatic sulfur compound, for example such as a thiaarane.

In another aspect of the invention, at least one fused-ring cyclic structure comprises at least one polycyclic aromatic nitrogen compound, for example such as an azaarane.

In another aspect of the invention, at least one fused-ring cyclic structure comprises at least one polycyclic aromatic oxygen compound, for example such as an oxaarane.

In one aspect of the invention, heterocyclic ring moieties within larger fused-ring molecules are used to create structural variations with ring current properties that differ from the ring currents in polycyclic aromatic hydrocarbons.

In another aspect of the invention, heterocyclic ring moieties within larger fused-ring molecules are leveraged to provide signal input and output capabilities that differ from those available in polycyclic aromatic hydrocarbons.

### Functional Group Aspects of the Invention

In an aspect of the invention, at least one functional group within the fused-ring molecule comprises a heterocyclic structure.

In an aspect of the invention, at least one functional group within the fused-ring molecule comprises an aromatic moiety.

In another aspect of the invention, the fused-ring molecule comprises at least one capability rendered or influenced by at least one attached functional group.

In another aspect of the invention, the fused-ring molecule comprises at least one behavior rendered or influenced by at least one attached functional group.

### Coordination Complex and Chelate Aspects of the Invention

In an aspect of the invention, a fused-ring molecule comprises a coordination complex.

In another aspect of the invention, a fused-ring molecule comprises an cyclic chelate.

In another aspect of the invention, a fused-ring molecule comprises a sandwich compound structure.

In another aspect of the invention, a fused-ring molecule comprises a half-sandwich compound structure.

In another aspect of the invention, a fused-ring molecule comprises a metallocene.

In another aspect of the invention, a fused-ring molecule comprises a metalloporphyrin structure.

In another aspect of the invention, the fused-ring molecule comprises a charge transfer complex.

### Supramolecular, Macromolecular, and Polymer Aspects of the Invention

In an aspect of the invention, a fused-ring molecule is comprised by a larger supramolecular structure.

In another aspect of the invention, a fused-ring molecule comprises a supramolecular structure.

In another aspect of the invention, a fused-ring molecule comprises at least one polymer.

In another aspect of the invention, a fused-ring molecule comprises at least one metallocene polymer.

In another aspect of the invention, a fused-ring molecule comprises at least one block polymer.

In another aspect of the invention, a fused-ring molecule comprises at least one cross-linked polymer.

In another aspect of the invention, a fused-ring molecule comprises a host-guest structure.

In another aspect of the invention, a fused-ring molecule is comprised by a host-guest structure.

### Fabrication Aspects of the Invention

In another aspect of the invention, a desired arrangement of a plurality of fused-ring molecules is fabricated by polymerization.

In another aspect of the invention, a desired arrangement of a plurality of fused-ring molecules is fabricated through the use of self-assembled monolayers.

In another aspect of the invention, a desired arrangement of a plurality of fused-ring molecules is fabricated through the use of molecular recognition assembly.

In another aspect of the invention, a desired arrangement of a plurality of fused-ring molecules is fabricated through the use of DNA-driven assembly.

### BRIEF DESCRIPTION OF THE DRAWINGS

The above and other aspects, features and advantages of the present invention will become more apparent upon consideration of the following description of embodiments taken in conjunction with the accompanying drawing figures. The accompanying figures are examples of the various aspects and features of the present invention and are not limiting either individually or in combination.

FIG. 1 depicts a high-level summary of some aspects of the invention.

FIGS. 2a-2d depicts benzene rings.

FIG. 3 illustrates a vertically depicted externally sourced magnetic field line intersecting a perpendicular planar molecule.

FIGS. 4a-4f depict examples of homoaromatic compounds.

FIG. 5a depicts the induction of ring current from a circularly polarized laser pulse, and a subsequently magnetic field induced by the ring current. FIG. 5b depicts the ring currents induced in a metal porphyrin a circularly polarized laser pulse.

FIG. 6a depicts an example molecule involving three fusings of benzene rings to a selected benzene ring.

FIG. 6a depicts an example molecule involving four fusings of benzene rings to a selected benzene ring.

FIG. 7 illustrates a family of polycyclic hydrocarbons that involve a circular structure of benzene rings.

FIG. 8 depicts planar aromatic fused-ring molecules comprised by all carbon ring atoms with non-hexagonal moieties (azulene, acenaphthylene, acenaphthene, and fluorantheses).

FIG. 9 depicts a region of the periodic table local to carbon comprising elements relevant to heterocyclic compounds and inorganic cyclic compounds.

FIGS. 10a-10d depict the π-cloud of a simple benzene ring and representative examples of how heteroatom lone pairs of electrons can be adapted as constituents in the π-cloud of a single-ring heterocyclic compound.

FIGS. 11a-11f depict examples of 5-member and 6-member heterocyclic-compounds with one to three hetero-atoms of various types.

FIG. 12 depicts six topologically-distinct fused-ring molecules where in each six-member ring comprises a single nitrogen atom and where in none of the nitrogen atoms are located at the ring fusion bond between the two six-member rings.

FIGS. 13a-13d depict the fusion of a six-member ring and a five-member ring where in a nitrogen atom serves as a member of the ring fusion bond.

FIG. 14 depicts a three-ring fused molecule with nitrogen heteroatoms.

FIG. 15 depicts a more complex molecule including one six-member ring moiety comprising two nitrogen molecules as well as several benzene rings and a seven-member ring.

FIG. 16a depicts a number of aromatic fused-ring molecules comprising one heterocyclic moiety and one benzene ring moieties. FIG. 16b depicts an aromatic fused-ring molecule comprising one heterocyclic moiety and two benzene ring moieties. FIG. 16c depicts fused-ring molecules comprising two heterocyclic moieties and two benzene ring moieties.

FIGS. 17a-17e depict more complex fused-ring molecules comprising aromatic two-nitrogen six-member heterocycle moieties and benzene ring moieties.

FIGS. 18a-18b depict fused-ring molecules comprising aromatic three-nitrogen six-member heterocycle moieties and benzene ring moieties.

FIGS. 19a-19b depicts a fused-ring molecule comprising aromatic nitrogen-hetero-atom five-member and six-member heterocycle moieties two benzene ring moieties.

FIGS. 20a-20b depict more complex fused-ring molecules comprising sulfur-based aromatic heterocycle moieties and benzene ring moieties.

FIGS. 21a-21c depict fused-ring molecules comprising moieties with nitrogen and oxygen heteroatoms.

FIGS. 22a-22g depict fused-ring molecules comprising moieties with nitrogen and sulfur heteroatoms.

FIG. 23 depicts a fused-ring molecule comprising larger-ring heterocyclic moieties therein comprising oxygen and sulfur heteroatoms.

FIG. 24 depicts a fused-ring molecule comprising heterocyclic moieties therein comprising oxygen and phosphorus heteroatoms.

FIGS. 25a-25d depict fused-ring molecules comprising heterocyclic moieties therein comprising nitrogen (Group 15) and other heteroatoms (Group 15 phosphorous; Group 16 sulfur, selenium; Group 14 tin, silicon). FIGS. 25e-25f depict bridgehead nitrogen heteroatoms.

FIGS. 26a-26c depict photochromic compounds and processes.

FIGS. 27a-27d depict the pH indicator molecule phenolphthalein in various pH conditions.

FIGS. 28a-28c depict the thymol blue (thymolsulphonephthalein) molecule in various pH conditions.

FIG. 29a shows a representation of the one-dimension time-varying magnetic stimulus used to induce ring currents that were depicted earlier in FIG. 3.

FIG. 29b depicts three orthogonal magnetic field directs that can be used for “powering” (inducing ring currents) and/or signal inputs and/or signal outputs.

FIGS. 30-34 depict molecular fused-ring systems that are nonplanar.

FIGS. 35-36 depict bridge structures in a fused-ring molecules.

FIG. 37a depicts a schematic representation of a fused-ring molecule. FIG. 37b depicts overlapping a-orbitals of the fused-ring molecule depicted the schematic representation of FIG. 37a.

FIGS. 37c-37e depict the overlapping p-orbitals for each of the individual ring moieties in fused-ring molecule depicted the schematic representation of FIG. 37a. FIG. 37f depicts the overlapping p-orbitals for all of the ring moieties in fused-ring molecule depicted the schematic representation of FIG. 37a. FIG. 37g depicts the overlapping p-orbitals of FIG. 37f with the overlapping σ-orbitals of FIG. 37b.

FIG. 38 depicts, from bottom to top, the overlapping σ-orbitals of FIG. 37b, its schematic representation of FIG. 37a, each of three ring current components confined to each of the ring moieties, three pair-wise perimeter internal ring currents between pairs of ring moieties, and the outer perimeter ring current.

FIGS. 39a and 39b depict mesh current components for two abstract fused-ring structures. The collection of mesh current components of FIG. 39a can be viewed as isomorphic to the collection of ring current components of FIG. 38.

FIG. 40 shows an electronic circuit comprising a photonic input, a voltage input and a voltage output.

FIG. 41 depicts an abstraction of electronic circuits comprising a photonic input, a voltage input and a voltage output.

FIG. 42a depicts another electronic circuit comprising two photonic inputs and a voltage output. FIG. 42b depicts a molecular electronic circuit comprising two photonic inputs and a measurable or couplable phenomena output.

FIG. 43 depicts an abstraction of the molecular electronic circuit of FIG. 42b.

FIGS. 44a-44e depicts various coupling mechanisms between electronic circuit elements involving at least one current.

FIGS. 45a-45b depict crown ethers fused with aromatic ring compounds.

FIGS. 46a-46c and 47a-47c depict nitrogen-boron fused-ring compounds.

FIGS. 48a-48c depict nitrogen-phosphorus fused-ring compounds.

FIG. 49 depicts a cluster compound.

FIGS. 50-52 depict porphyrins and related compounds.

FIG. 53 depicts types of chlorophyll, a type of porphyrin.

FIG. 54 depicts the shift in photonic spectra resulting from the slight differences in functional groups.

FIGS. 55a-55c depict metallic porphyrin complexes. FIG. 55d depicts a metallic porphyrin complex comprising a bridge that additionally provides field influences on the complexifying metal ion. FIG. 55e depicts polymers that can be created from planar metallic porphyrin complexes.

FIGS. 56a-56c and FIG. 57 depict exemplary ferrocenes.

FIG. 58 depicts an Ti-based metallocene.

FIG. 59 depicts a ring Ni-based and Fe-based metallocene.

FIG. 60a-60c depict aniline orbitals and resonance forms.

FIG. 61 depicts and example charge transfer complex.

### DETAILED DESCRIPTION

In the following description, reference is made to the accompanying drawing figures which form a part hereof, and which show by way of illustration specific embodiments of the invention. It is to be understood by those of ordinary skill in this technological field that other embodiments can be utilized, and structural, electrical, as well as procedural changes can be made without departing from the scope of the present invention. The aspects and features described herein may be used singly or in combination unless specifically stated otherwise.

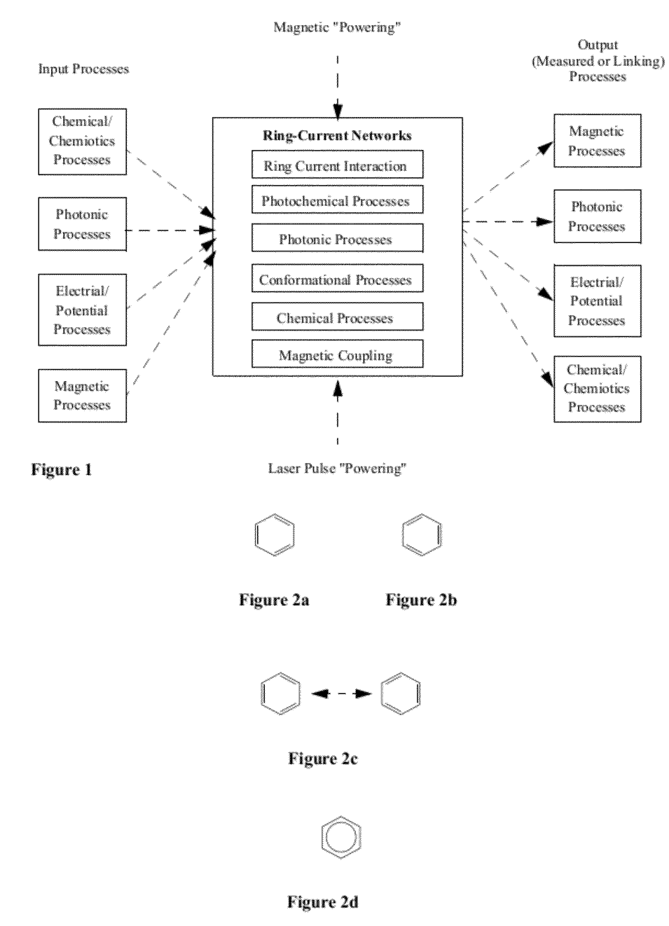

The present patent application respectfully submits a fundamentally new framework for molecular-scale signal processing and digital logic by repurposing ring currents as an electronic circuit without wires. FIG. 1 depicts a high-level summary of some aspects of the invention. In the broadest reaches of the invention, one or more of chemical processes, chemionics processes, photonic processes, electrical/potential processes, and magnetic processes serve as one or more signal input(s) to one or more coupled or isolated ring current networks. The one or more of these ring current networks provide one or more signal output(s) in the form of one or more of chemical processes, chemionics processes, photonic processes, electrical/potential processes, and magnetic processes that are measured, linked, or otherwise observed by external or exogenous systems. The ring currents themselves are induced by one or more sources of time-varying magnetic field(s) or laser pulse(s) (for example, short-duration circularly polarized laser pulses) that are applied to the one or more coupled or isolated ring current networks

To begin, attention is first directed to the case of the simple benzene ring, depicted in various ways in FIGS. 2a-2d.

In standard atomic orbital models, carbon atom is structured to quiescently comprise five distinct electron orbitals considered; these are traditionally designated 1s, 2s, 2pₓ, 2p_{y}, 2p_{z}. A carbon atom has six electrons, and in the ground (unexcited) state has two electrons located in the 1s atomic orbital, two electrons within the 2s atomic orbital, and one electron in two of the three 2p atomic orbitals (2pₓ, 2p_{y}, 2p_{z}). The third 2p orbital is vacant in the ground state.

In many molecular configurations, one of the 2s electrons is excited (under the influence of electric fields) out of the 2s atomic orbital (leaving the 2s atomic orbital with one electron) and into the vacant 2p atomic orbital. The result under these conditions is two electrons in the 1s atomic orbital, one electron in the 2s atomic orbital, and one electron apiece in each of the three 2p atomic orbitals 2pₓ, 2p_{y}, 2p_{z}.

In alkanes (hydrocarbons only single-bonds between bounded carbon atoms), a carbon atom's three 2p atomic orbitals (2pₓ, 2p_{y}, 2p_{z}) combine with that carbon atom's single 2s atomic orbital to form four hybridized sp³ orbitals, each comprising one electron and each symmetrically oriented in 3-space at ˜109.5-degree angles in the shape of a tetrahedron.

In alkenes (hydrocarbons with at least one double-bound between bounded carbon atoms) such as the benzene ring, a corresponding model combines the single 2s atomic orbital with only two of the three 2p atomic orbitals (leaving the third 2p atomic orbital uninvolved). The result is one comprising three hybridized sp² atomic orbitals plus the remaining p orbital. The three hybridized sp² orbitals line in a plane, trisecting it in 120-degree angles in the shape of an equilateral triangle, while the p atomic orbital is perpendicular to the plane. Because the hybridization has less p-orbital components, quantum statistics weigh more 2s significance in the electron distribution within the three hybridized sp² atomic orbitals (as compared to hybridized sp³ atomic orbitals which ‘average in’ three 2p atomic orbitals rather than two). As a result these three hybridized sp² atomic orbitals are thus statistically located closer to the carbon atom nucleus that that of the uninvolved p atomic orbital. The hybridized sp² atomic orbitals of two separate but sufficiently adjacent carbon atoms can overlap to form a bond between these carbon atoms—such a bond (between hybridized sp² atomic orbitals of two separate carbon atoms) is known as σ-bond. Note the p atomic orbital of each of the σ-bonded carbon atoms is thus subsequently geometrically orthogonal to the resulting σ-bond between the bounded carbon atoms.

A benzene molecule comprises six carbon atoms links by σ-bonds to form a ring comprised of six single σ-bonds. Because the sp² atomic orbitals of each carbon atom line in a plane, the resulting benzene ring is planar. In each carbon atom, p atomic orbital is orthogonal to the plan of that carbon atom's three sp² atomic orbitals. Thus the geometry of the p atomic orbitals of the six carbon atoms cause each of the six p atomic orbitals to overlap with the p atomic orbital of each of its two immediate neighbors. This overlapping provides the basis for a second bond between adjacent carbon atoms. However, the overlap and atomic orbital geometry is such that the electron distribution situation within the lesser overlapping p atomic orbitals is more relaxed than that of the greater overlapping σ-bonds, and in fact the six electrons in the p atomic orbitals are found both theoretically and empirically to be equally distributed among each of the six p atomic orbitals in the benzene molecule. The resulting additional “bonds” resultant from the lesser overlapping p atomic orbitals are referred to as π-bonds, but because of the equally distributed nature of the electrons the resulting arrangement is referred to as a π-cloud. The equally distributed electrons in the π-cloud are referred to as ‘delocalized.’

Certain conditions can force the bonds into specific static configurations in the benzene ring involving three single bonds (each a σ-bond only) and three double bonds (each a σ-bonds plus a rigidly defined π-bond), for example as depicted in FIG. 2a or FIG. 2b. However, in most cases the benzene ring “simultaneously” behaves as both and neither of FIG. 2a and FIG. 2b—instead, as it now modeled, the six electrons in the p atomic orbitals are equally distributed among each of the six p atomic orbitals. Early views of Pauling and others likely envisioned the benzene ring “simultaneously” behaves as both and neither of FIG. 2a and FIG. 2b in a different manner, or at least employed use the misleading term “resonance” together with diagrams such as that depicted in FIG. 2c to represent that model. However, in the contemporary view, nothing in the electron structure of benzene is thought to be oscillating in such a manner [1] and eventually new terminologies and symbols, such as that depicted in FIG. 2d, became proposed and adopted. Of importance is that benzene and other molecular rings can be fused so as to share a common pair (or more) of atoms and their associated bonds (resulting in a fused-ring (“condensed ring”) molecule.

### 1. Ring Currents

Ring currents in cyclic molecules came to and have remained in the attention of researchers due to their role in the spectrometric identification of organic compounds. Ring current models are used to explain various observed magnetic spectrometric measurement shifts and have been the subject of a large number of books and articles, including those disputing their existence.

### 1.1 Magnetically Induced Ring Currents

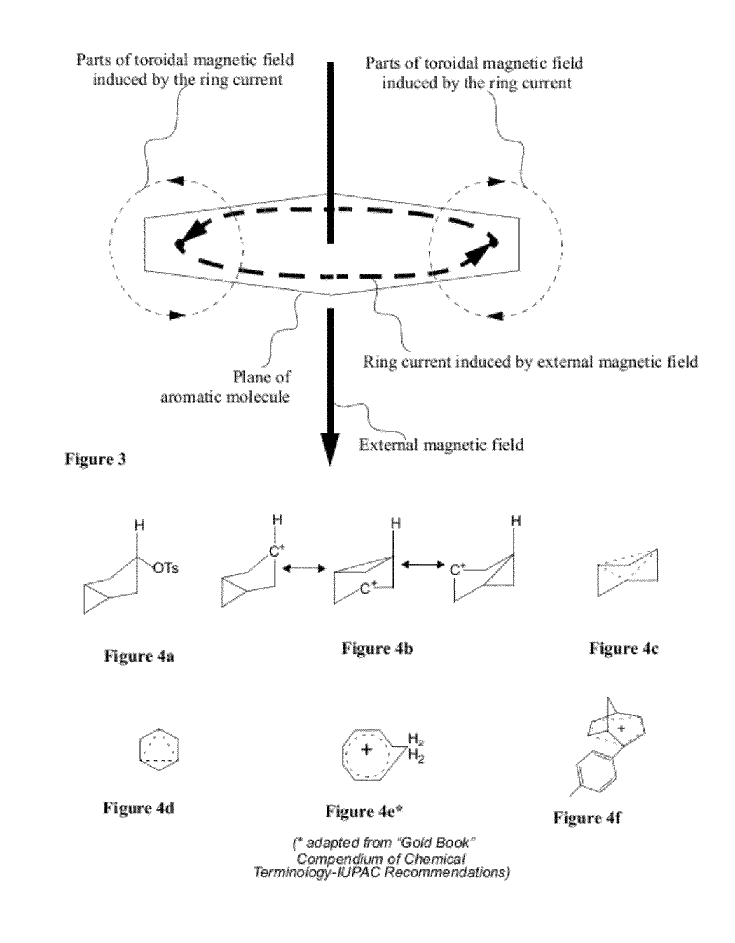

FIG. 3 which illustrates a vertically depicted externally sourced magnetic field line intersecting a perpendicular planar molecule.

By Faraday's Law, electrons in an aromatic planar-aligned molecule's n-orbitals are forced to flow in a circular path as a current induced by (and proportional to) the time-derivative of the external magnetic field. By Ampere's law, the resultant electron current itself induces a toroidally-origined magnetic field proportional to the time-derivative of the electron current. It is this Ampere's law induced magnetic field that is used to make traditional Nuclear Magnetic Resonance (NMR) measurements used to character details of molecules under study. In many molecular rings, the induced ring currents are subsequently sustained after being induced.

Although the history has been long, detailed, and somewhat convolved, the term “aromatic,” which had been used to signify first compounds similar to benzene, then used to signify compounds with benzene-like stability, has now come to signify compounds exhibiting diatropic ring currents (also called ‘diamagnetic ring currents’ and ‘aromatic ring currents’). There have subsequently emerged large number of types of aromaticity, concepts related to aromaticity, various types of ring current phenomena, and conditions in various way differing from aromaticity. Some of these relevant to the invention include these two opposing components:
“paratropic” ring currents that flow ‘inside’ of a molecular ring
“diatropic” ring currents that flow ‘outside’ of a molecular ring
and the following uses of these components:
“non-aromatic” molecules where paratropic ring currents and diatropic ring currents are equal and opposite, effectively cancelling out one another;
“aromatic” molecules where the diatropic ring current on the outside of the ring dominates the paratropic ring current inside of the ring;
“antiaromatic” molecules where the paratropic ring-current inside the ring dominates the diatropic ring current on the outside of the ring,
   Even though all molecular rings can be viewed as supporting both diatropic and paratropic ring current components when exposed to an external magnetic field, “aromatic” molecules are grossly said to support “only” diatropic ring currents, “antiaromatic” molecules are grossly said to support “only” paratropic ring currents, and “non-aromatic” molecules are grossly said to support “no” ring currents.

In some compounds ring current transported by π-electrons flows only on one side of a ring plane [2].

The breakthough formulation of Hückel's rule states an aromatic molecule must be planar and cyclic and have (4n+2) π-electrons that form an uninterrupted π-electron cloud. The bonding π molecular orbitals are fully occupied, while the non-bonding π molecular orbitals and the antibonding molecular orbitals are completely unoccupied. In the Hückel theory, if the molecule is not both planar and cyclic then it cannot not aromatic. There are various other predictive results, for example involving conjugated structures within molecular rings, and subsequently many curious extensions and counterexamples (for example, pyrene has sixteen π electrons and coronene has twenty-four π, each violating the (4n+2) π-electron criterion, but both are aromatic carbon compounds). As a result, the original Hückel theory has been extended considerably, for example admitting important variations including:
“strain” ring currents that arise from strain conformations within a unconjugated molecular rings;
“homoaromatic” ring currents, found in conjugated cyclic systems that are able to skip a part of the ring.
   Although hardly comprehensive, a representative quick summary may be found in quoting the abstract of the analytic molecular orbital paper by Fliegl et al. [2]:
“The magnetically induced current densities for ring-shaped hydrocarbons are studied at the density functional theory (DFT) and second-order Møller-Plesset (MP2) levels using gauge-including atomic orbitals. The current densities are calculated using the gauge-including magnetically induced current approach. The calculations show that all studied hydrocarbon rings sustain strong diatropic and paratropic ring currents when exposed to an external magnetic field, regardless whether they are unsaturated or not. For nonaromatic rings, the strength of the paratropic current flowing inside the ring is as large as the diatropic one circling outside it, yielding a vanishing net ring current. For aromatic molecules, the diatropic current on the outside of the ring is much stronger than the paratropic one inside, giving rise to the net diatropic ring current that is typical for aromatic molecules. For antiaromatic molecules, the paratropic ring-current contribution inside the ring dominates. For homoaromatic molecules, the diatropic current circles at the periphery of the ring. The ring current is split at the CH(2) moiety; the main fraction of the current flow passes outside the CH(2) at the hydrogens, and some current flows inside the carbon atom. The diatropic current does not take the through-space short-cut pathway, whereas the paratropic current does take that route. Calculations of the ring-current profile show that the ring current of benzene is not transported by the pi electrons on both sides of the molecular ring. The strongest diatropic ring current flows on the outside of the ring and in the ring plane. A weaker paratropic current circles inside the ring with the largest current density in the ring plane. Due to the ring strain, small unconjugated and saturated hydrocarbon rings sustain a strong ring current which could be called ring-strain current.”

The understanding of molecular orbitals and ring currents of benzene, other cyclic hydrocarbons, and polycyclic hydrocarbons has subsequently been significantly developed. The new terminologies and symbols are reflective of more detailed understanding and development of molecular orbital (MO) models. As is known to one skilled in the art, a vast number of analytic molecular orbital models and calculations exist; for example but hardly limited to Linear Combination of Atomic Orbital (LCAO) method, Hartree-Fock method, Self-Consistent-Field methods, Ab Initio methods, Møller-Plesset Perturbation methods (1^{st} order, 2^{nd} order, etc.), Density Functional Theory (DFT) method, Semiempirical methods, complete-active-space self-consistent field (CASSCF) methods, Ipsocentric method, Gauge-Including Atomic Orbital (GIAO) methods, Continuous Set of Gauge Transformation (CSGT) methods, etc. These theories, methods, and associated empirical studies encompass many other types of related bond phenomena. One example is hyperconjugation (comprising an extended molecular orbital involving interactions of sigma bond electrons with a proximate unfilled non-bonding p-orbital, unfilled antibonding π orbital, or filled π orbital) as well as more complex doubly or triple aromatic situations (comprising two or more of σ-, π-, and δ-electron systems). Neutral planar rings of carbon atoms can exhibit “double aromaticity” support ring currents associated with in-plane π-electron systems as well as the usual out-of-plane π-electron systems. Another important case is that of excited states: many individual and fused-ring molecules (for example, benzene, cyclobutadiene, azulene, porphyrins) exhibit ring currents in excited states, and some molecules are have ring currents in excited states and exhibit opposite [3] or no ring currents in the ground state. Azulene is also known to exhibit oscillating ring currents in its second excited state [3].

### 1.2 Homoaromatic Ring Currents

As described above, “homoaromatic” ring currents are ring currents induced in conjugated molecular ring that are able to skip one or more atoms of the ring. Compounds with this property are often referred to as being homoaromatic. FIG. 4a, when ionized, has the resonant forms depicted in FIG. 4b. On the balance these behave as the homoaromatic structure depicted in FIG. 4c. FIGS. 4c-4f depict a number of other examples of homoaromatic compounds. These interesting structures and their properties provide a wider pallet from which systems with pluralities of ring currents can be constructed.

1.3 Ring Currents in Non-Planar Molecules with Orthogonal Cyclic Structures

Some polycyclic molecules (molecules have a plurality of cyclic structures) are arranged so that at least two cyclic structures lie in different planes oriented at angles with respect to one another. One case of interest pertains to molecules where the planes are orthogonal. Some molecules of this type can be “multiply” aromatic, for example comprising at least one aromatic system in a first plane and at least one other aromatic system in a second plane orthogonal to the first plane. The 3,5-dehydrophenyl cation is an example [4].

### 1.4 Circularly-Polarized Laser-Pulse Induced Ring Currents

Traditionally molecular ring currents have been induced only by magnetic fields, typically those involved in Nuclear Magnetic Resonance (NMR) measurements and instrumentation. However, work of Barth [5]-[7] and others to follow have predicted that a very-short duration circularly-polarized laser pulse can induce a ring current in at least excited degenerate states of a molecule capable of supporting ring currents in at least excited states of the molecule. Theoretical calculations suggest the strength of the induced ring current can be of considerable magnitude. This not only provides an important alternative and/or supplement to the use of magnetic fields to induce molecular ring currents employed by the invention, this also augments the design pallet for the invention yet further:
Additional degrees of control are provided via the amplitude, wavelength, duration of the laser pulse;
The direction of the circular polarization of the laser light controls the direction of the current;
Magnetic fields can be generated by the induced ring current. FIG. 5a (adapted from [5]-[6]) depicts the induction of ring current from a circularly polarized laser pulse, and a subsequently magnetic field induced by the ring current. Since the direction of a circular electron current determines the direction of an induced magnetic field, the direction of the circular polarization of the laser light thus also controls the direction of the induced magnetic field;
Since some molecules (for example, azulene [3]) have differing ring current properties in excited states than in ground states, this laser pulse excitation can be used to modulate ring current properties (aromaticity, anti aromaticity, etc.);
Since some molecules (for example, again, azulene [3]) exhibit oscillating ring currents in excited states—attributed to interference effects between HOMO and LUMO—opportunities exists for simple molecular-scale oscillators that can be coupled via mesh currents in fused rings, induced magnetic fields, etc.);
Since excited states can be used to induce changed molecular conformation and other molecular rearrangements, the use of laser pulse stimulation can also be employed to invoke topological feature changes to moieties within the molecule;
Since chemistry in excited states differs considerable from chemistry in ground states, the use of laser pulse stimulation can also be employed to invoke excited state chemistry, for example involving reactive intermediates;
Since excited states can dissipate via photon emission of other wavelengths, the use of laser pulse stimulation can also be employed to invoke photonic processes within the molecule or among a group of molecules.
In topologically complex molecules, the use of laser pulse stimulation can be used to induce ring currents with different flow topologies than would be produced by time-varying magnetic fields. For example FIG. 5b (adapted from [5]-[6]) depicts the ring currents induced in a metal porphyrin a circularly polarized laser pulse

### 2. Fused-Ring Molecules

Fused-ring molecules exhibit a plurality of ring currents, and the overall gross ring current behavior can be represented as a linear combination of local ring current components. This is analogous to multi-mesh electrical circuits as will be described later, and provides an important framework for the invention.

Within the structures of each employed ring in a fused-ring molecule, delocalized electrons of a π-cloud (including associated lone pairs, hybridized orbital electrons, etc) of a fused-ring molecule (among other possible Mechanisms) provide mutual interaction among ring currents. This interaction is influenced by at least the topology and geometry of the fused-ring molecule.

An important step relating to the understanding of the structure of ring currents was the work of Clar and its subsequent refinements. These, in the case of (homogeneous-moiety, i.e., only benzene rings) polycyclic aromatic hydrocarbons (“PAH”, discussed further below), force surprisingly vast non-symmetries in the relative strengths of ring current components within the mesh topology implied by the nucleus locations comprised by a fused-ring molecule. The aforementioned work of Clar and others that followed predict and demonstrate that the ring currents in a fused-ring molecule comprise aromatic sextet structures. In general, the ring currents in a fused-ring molecule can be represented as comprising a superposition of various local and global ring currents. More details and examples are provided in Section 5.

### 2.1 Polycyclic Hydrocarbons and Related Compounds

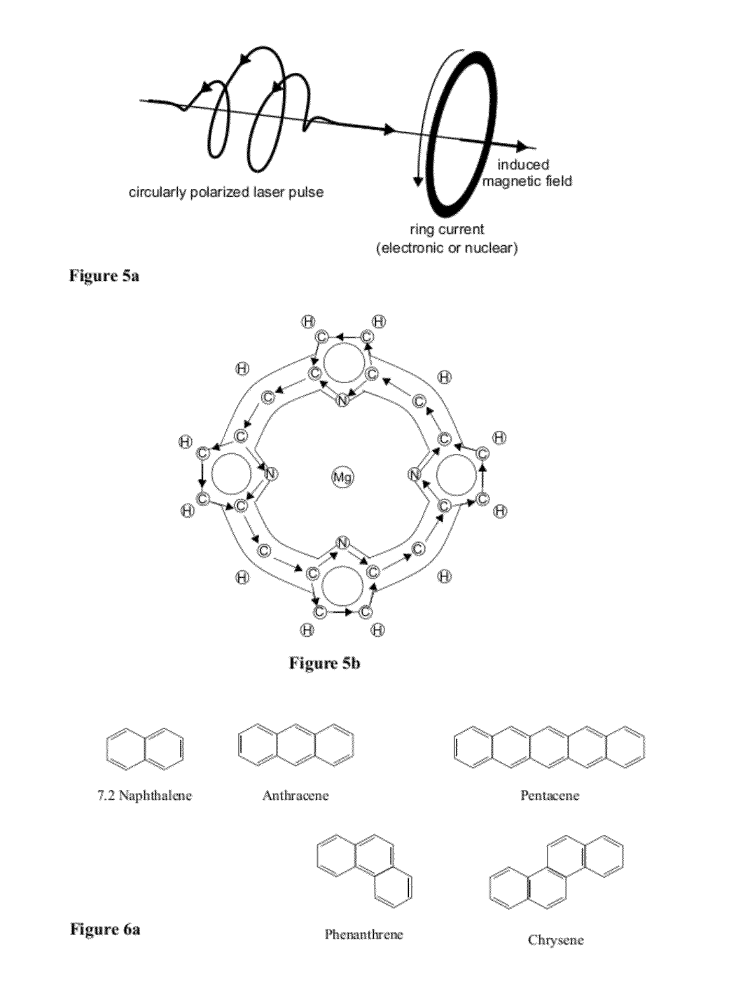

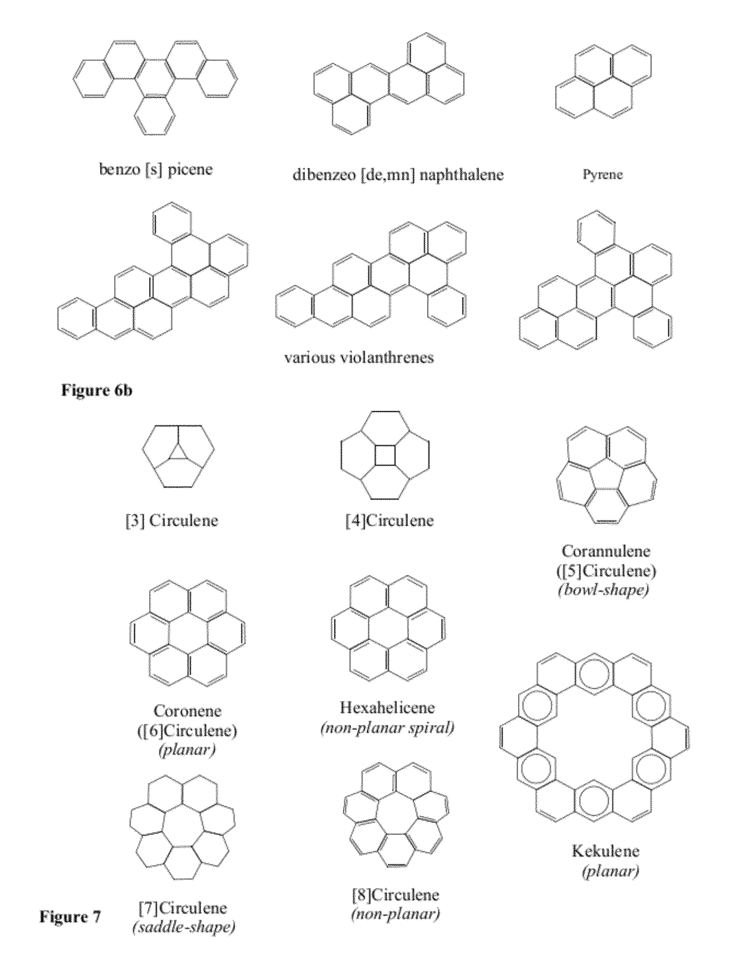

The member atoms of the molecular rings may be augmented with various atoms (such as hydrogen) or functional groups. Important to the invention, two or more such benzene rings may be fused share a common pair (or more) of atoms and their associated bond(s), and the resultant fused-ring molecule is aromatic. Several examples are shown in FIG. 6a. Note that, unlike the usual situation where the electrons in the π-cloud are delocalized, the compounds of FIG. 6a.demonstrate localization of their double bonds.

More complex and larger-scale fusings of benzene rings also exist, for example involving three fusings to a given ring as shown in the examples of FIG. 6a (Benzso[5]picene and dibenzo[de,mn]naphtalene, and pyrene), four fusings to a ring as in the example violanthrenes of FIG. 6b, as well as five and six fusings. When all free bonds are saturated with hydrogen, the resulting fused-ring compounds are examples of a broad class of compounds known as polycyclic hydrocarbons. Molecular orbitals of these have been highly studied empirically and theoretically.

Many polycyclic hydrocarbons have been determined empirically and analytically determined to be aromatic. Polycyclic hydrocarbons that are aromatic are well-studied and have become known as Polycyclic Aromatic Hydrocarbons (PAH). Polycyclic hydrocarbons include many interesting topologies which, as will be seen, can bring in other associated properties. In many cases the property of being aromatic does not depend on hydrogen and other radicals or functional groups may be used instead. There are exceptions, for example a ring current within a moiety of tetrakis(bicyclo[2.1.1]hexeno)cyclooctatetraene (1(D₄ₕ)) can be modulated on or off via saturated or unsaturated clamps [8].

FIG. 7 illustrates a family of polycyclic hydrocarbons that involve a circular structure of benzene rings. Of these, the circulene family includes both coronene which due to the central hexagonal core, has essentially an unstrained form where the ring bared geometry of each ring is very close to that of benzene for every bond, allowing the molecule to be flat (planar). Other members of the circulene family comprise a non-hexagonal core and as a result can have non-planar shapes. In the case of [7]-circulene, the molecule has a saddle shape and [5]-circulene is bowl-shaped. It is noted that each of [5]-circulene, [6]-circulene, and [7]-circulene are aromatic although of these only [6]-circulene (a.k.a coronene) is planar. A variation in the flat conformal arrangement of coronene is hexahelicene which (as the helicene name suggests) has a helical structure. In circular topologies involving larger numbers of rings, other types of geometric structures emerge, such as the internal multidetent shape of the annular-shaped 12-ring planar molecule of Kekulene.

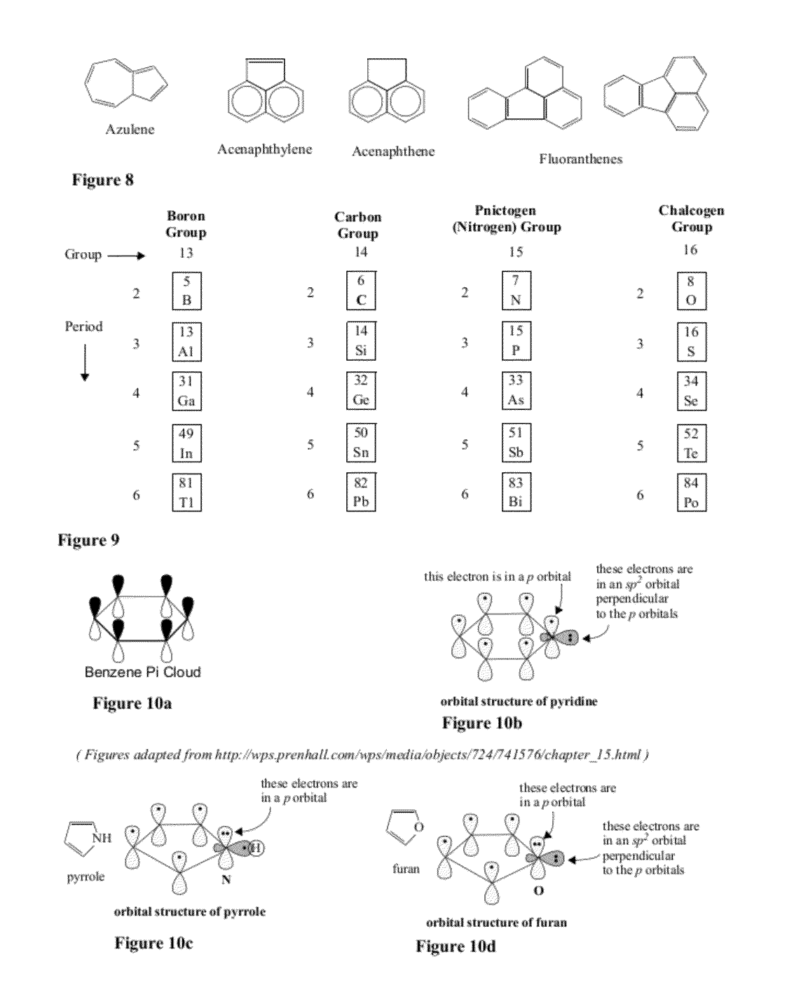

Thus, all the ringed moieties considered thus far are hexagonal in shape, for the most part maintaining the intrinsic tetrahedral shape of the hybridized sp³ atomic orbitals of each carbon atom. However, fused-ring molecules comprised by all carbon ring atoms with non-hexagonal moieties exist, for example azulene, acenaphthylene, and the fluorantheses as depicted in FIG. 8. Both acenaphthylene and the fluoranthene molecules are aromatic and planar. Despite the fact that azulene has no hexagonal rings, it is in fact aromatic (with a 10-electron π-cloud) and in quiescent situations the molecule is planar (some crystalline forms of azulene create electric fields that warp the otherwise planar azulene molecule).

### 2.2 Individual and Fused-Ring Heterocyclic Molecules

Of importance to the present invention are models, measurement data, and analysis pertaining to fused-ring carbon, heterocyclic and inorganic compounds. More will be provided on this topic later in the development and presentation of various aspects of the invention.

All of the fused-ring molecules described thus far have had only carbon as ring members and much of the discussion has been directed to aromatic molecules. However, molecules can comprise ring moieties containing ring atoms other than carbon, and aromatic molecules can occur in ring moieties with ring atoms other than carbon. Some of these are entirely inorganic, comprising atoms such as phosphorus, sulfur, boron, metals, etc. Other include at least one carbon atom

FIG. 9 depicts a region of the periodic table local to carbon. Through various mechanisms that create conditions for electron delocalization, these neighboring atoms become candidates for creating aromatic molecules by ‘replacing’ one or more carbon atoms. Under appropriate conditions these are reliably aromatic heterocyclic compounds, wherein each non-carbon atom that substitutes for a carbon atom (in a molecule also containing carbon members) is referred to as a ‘heteroatom.’ Because of variations in the election configurations of a heteroatom (non-carbon atoms) can readily produce aromatic rings with:
non-hexagonal geometrics (due to non-symmetric bound-lengths), and
non-hexagonal topologies (due to numbers of ring members other than six).

As to an initial view as to the degrees of variation, reference is again made to the region of the periodic table local to carbon depicted in FIG. 9. Because of valance differences of atoms outside group 14 from the valance of carbon, other mechanisms come into play in creating aromatic heterocyclic compounds. In some cases, lone pairs of Group 15 and Group16 heteroatoms can be used to “fill out” the π-cloud in such a way as to result in aromaticity.
Group 15 (Pnitogen) atomic orbitals can provide one lone pair of electrons, and
Group 16 (Chalcogen) atomic orbitals can provide two lone pairs of electrons.
   In some circumstances, Group 17 (Halogen) atomic orbitals can provide three lone pairs.

In the upper left corner of FIG. 10a the π-cloud of a simple benzene ring is provided for comparison while FIGS. 10a-10d provide a few representative examples of how heteroatom lone pairs of electrons can be adapted as constituents in the π-cloud of a single-ring aromatic heterocyclic compound.
In the case of benzene, every carbon atom in the ring contributes a p-orbital to create a π-cloud molecular orbital system which resides above and below the plane of the ring. The electrons in the π-cloud are evenly distributed around the plane of the ring.
In the case of pyridine, the single (sp² hybridized) nitrogen heteroatom keeps its extra lone pair free from the π-cloud and smoothly substitutes for a carbon atom to form a six-member ring resembling a benzene ring. The three double bonds provide the six electrons required to produce an aromatic π-cloud. The lone-pair electrons of the nitrogen atom are held in an sp2 hybrid orbital perpendicular to the orbitals in the π-cloud and are thus not part of the π-cloud. Instead, the remaining extra lone pair of the sp2 hybridized nitrogen atom is left for bonding outside the ring (i.e., to radicals and functional groups) and as a result gives pyridine a base pH.
In the case of pyrrole (a five member ring with one nitrogen heteroatom) the nitrogen atom lends its lone pair to the π-cloud resulting in a total of six π-cloud electrons to produce aromaticity. The nitrogen lone pair is oriented so that it becomes part of the π-cloud. The remaining extra electron of the sp2 hybridized nitrogen atom is left for bonding outside the ring to electrophiles (i.e., to hydrogen).
In the case of furan (a five member ring with one oxygen heteroatom) the oxygen atom lends one of its two lone pairs to the π-cloud resulting in a total of six π-cloud electrons to cause aromaticity. This first lone pair of oxygen replaces the electrons that would be provided by two carbon atoms in the benzene ring. (All atoms within the furan ring are sp2 hybridized.) This lone pair serves as part of the π-cloud. Since oxygen also has a second lone pair, the oxygen heteroatom provides an extra lone pair left for bonding outside the ring (i.e., to radicals and functional groups) which, as in the case of the lone pair from nitrogen in pyridine, gives furan a base pH. This second lone pair is in an sp2 hybrid orbital oriented perpendicular to the π-cloud (as is the single nitrogen lone pair in pyridine).
The case of thiophene (a five member ring with one sulfur heteroatom) is at the level of this discussion similar to that of furan, resultant from sulfur and oxygen both being Group 16 elements. The sulfur heteroatom lends a lone pair of electrons to the π-cloud, resulting in aromaticity. As with furan, thiophene has an extra lone pair of electrons provided by the sulfur atom to give the molecule a base pH character.

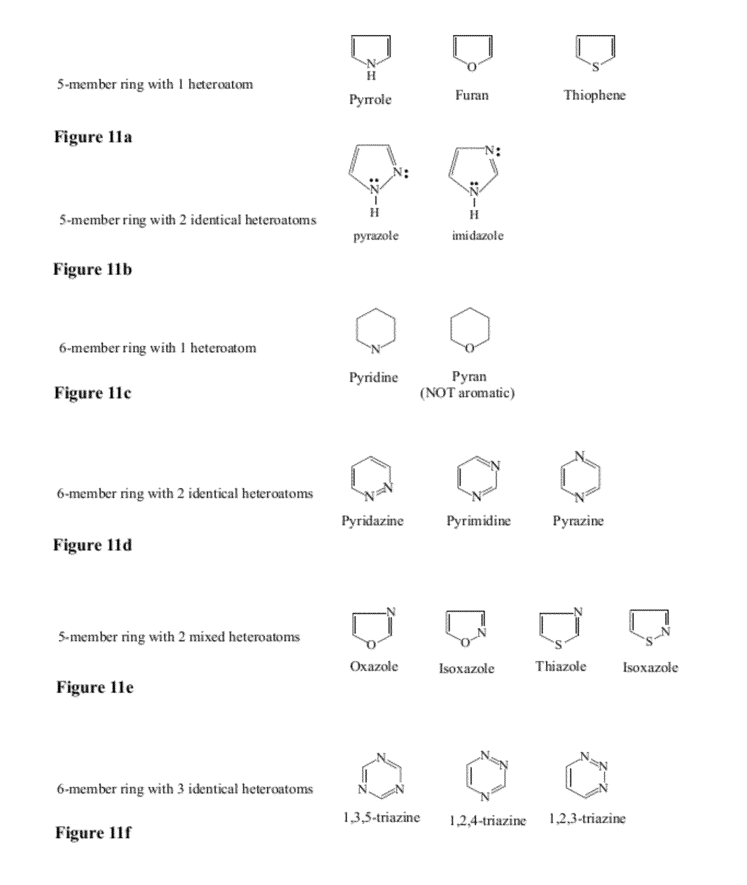

FIGS. 11a-11f depict various examples of 5-member and 6-member rings with one to three hetero-atoms of various types. FIG. 11a shows the similar structures of pyrrole and furan (considered in more detail just above) as well as that of thiophene wherein the Group 16 oxygen heteroatom is replaced with the Group 16 sulfur heteroatom. As described earlier, each of these is aromatic. FIG. 11b depicts pyrazole and imidazole which each contain two nitrogen heteroatoms wherein one of the nitrogen heteroatoms acts as the nitrogen heteroatom in pyridine (one electron contributed to the π-cloud) while the other nitrogen heteroatom acts as the nitrogen heteroatom in pyrrole (two electrons contributed to the π-cloud) as suggested by the dots (depicting the role of the lone pair) in these diagrams (dot-pair inside the ring are in the π-cloud, dot-pair inside the ring are not involved in the π-cloud). Each of these is also aromatic. FIG. 11c shows pyradine (described earlier) which is aromatic (due to the nitrogen contributing only its single sp² electron to the π-cloud, and pyran which (due to oxygen having two lone pairs) is not aromatic (too many electrons). FIG. 11d shows three two-nitrogen six-member rings which are aromatic due to each nitrogen ring contributing only its single sp² electron to the π-cloud. The examples of FIG. 11e (5-member rings with two mixed heteroatoms) and FIG. 11f (6-member rings with three nitrogen heteroatoms) are also aromatic.

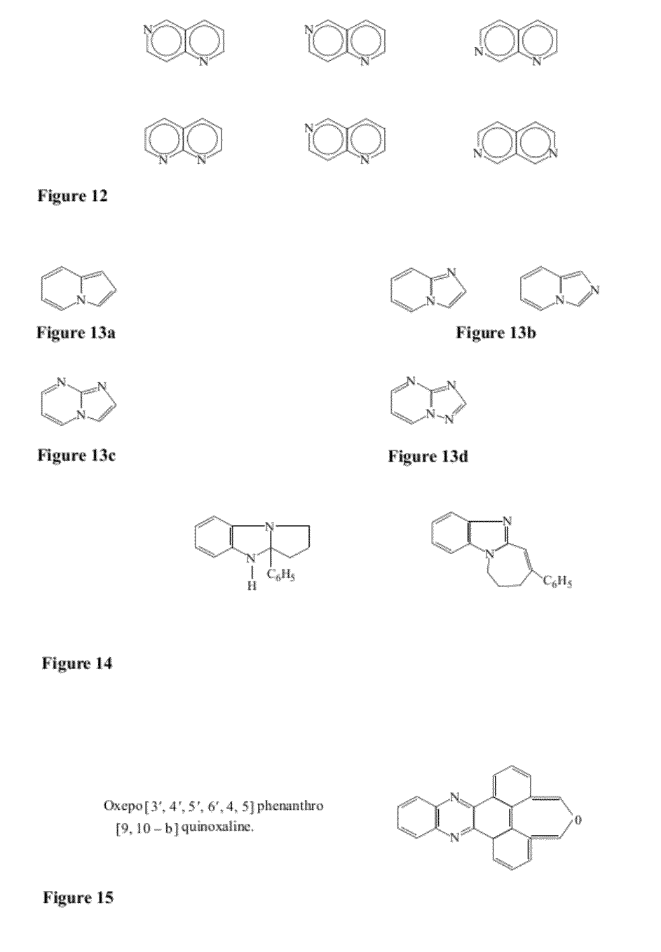

Although much of classical heterocyclic chemistry is concerned with heteroatoms of nitrogen, sulfur, and oxygen, the other atoms depicted in FIG. 9 also can be used to produce aromatic heterocyclic rings. As with the aromatic benzene ring, this rich collection of aromatic heterocyclic rings can be fused with one another or all carbon-member rings to produce fused-ring aromatic compounds. The presence of heteroatoms also makes various types of distinguishable configurations possible, such as the six topologically-distinct fused-ring variations depicted in FIG. 12 and two variations depicted in FIG. 13b (to be discussed shortly). FIG. 12 depicts six topologically-distinct fused-ring molecules where in each six-member ring comprises a single nitrogen atom and where in none of the nitrogen atoms are located at the ring fusion bond between the two six-member rings.

FIGS. 13a-13d depict the fusion of a six-member ring and a five-member ring where in a nitrogen atom serves as a member of the ring fusion bond. Of these FIG. 13a shows a case with one nitrogen atom, which FIGS. 13b-13d depict respectively, cases with 1, 2, and 3 additional nitrogen atoms not involved in the ring-fusion bond. FIG. 14 depicts a 3-ring fused molecule with nitrogen heteroatoms. FIG. 15 depicts a more complex molecule including one six-member ring moiety comprising two nitrogen molecules as well as several benzene rings and a seven-member ring.

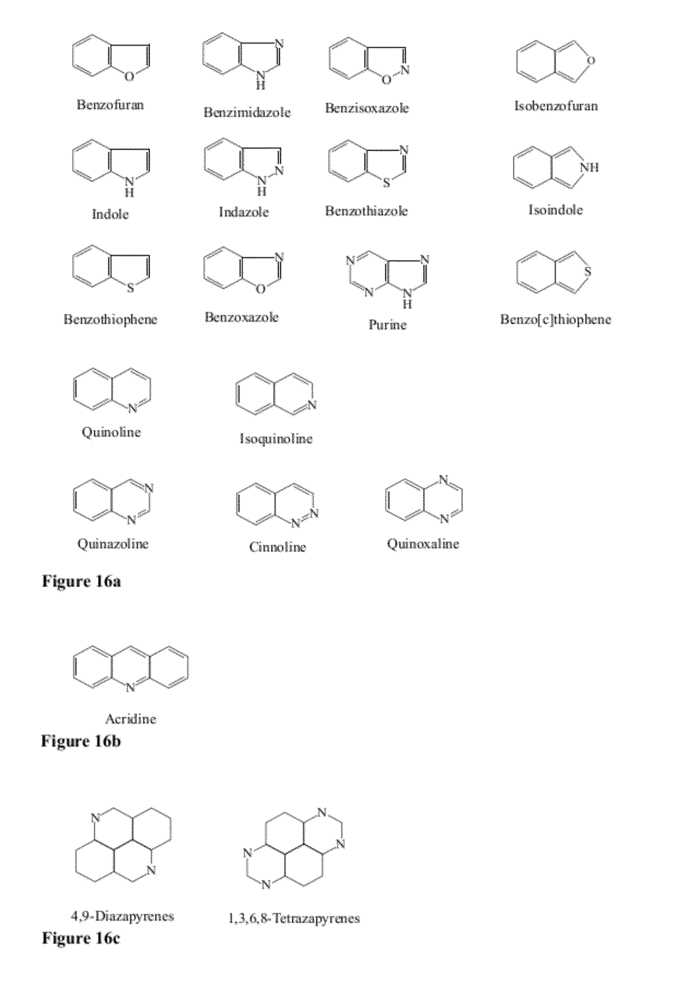

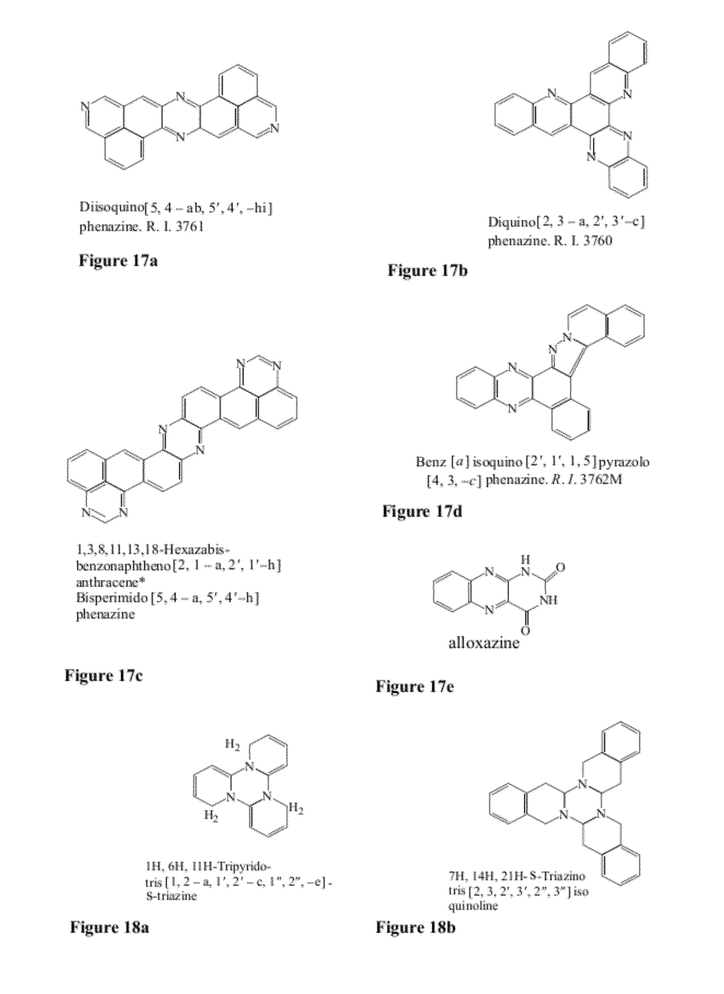

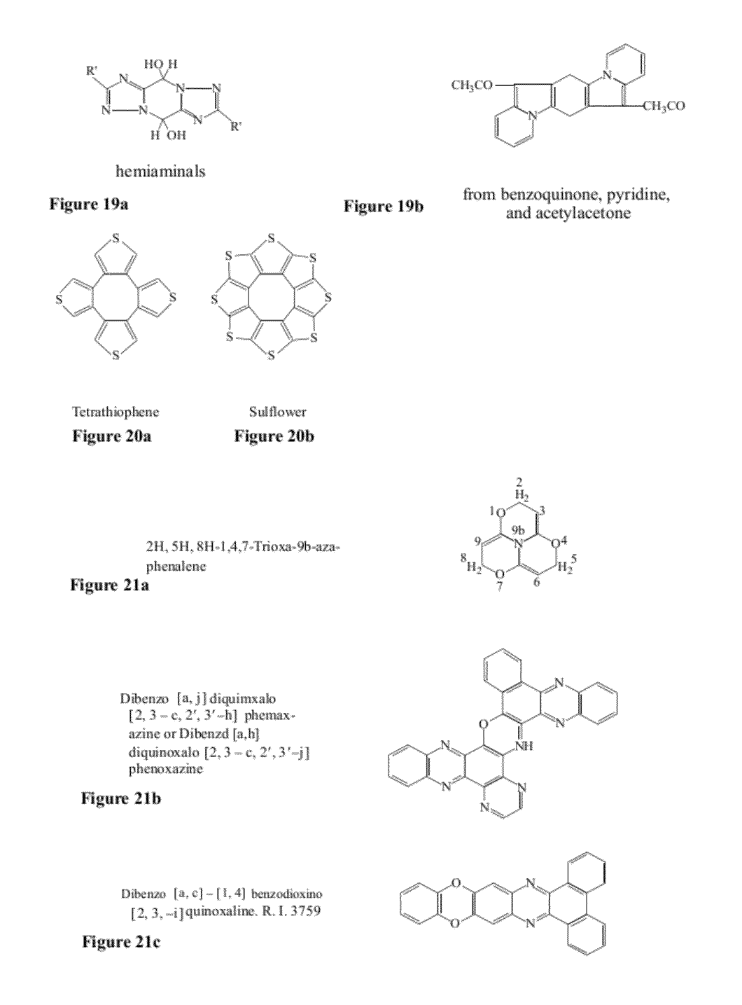

FIG. 16a depicts a number of aromatic fused-ring molecules comprising one heterocyclic moiety and one benzene ring moieties. FIG. 16b depicts acridine, an aromatic fused-ring molecule comprising one heterocyclic moiety and two benzene ring moieties. FIG. 16c depicts fused-ring molecules comprising two heterocyclic moieties and two benzene ring moieties. FIGS. 17a-17e depict more complex fused-ring molecules comprising two-nitrogen heteroatom aromatic six-member heterocycle moieties and benzene ring moieties. FIGS. 18a-18b depict fused-ring molecules comprising aromatic three-nitrogen six-member heterocycle moieties and benzene ring moieties. FIGS. 19a-19b depict fused-ring molecules comprising aromatic nitrogen-hetero-atom five-member and six-member heterocycle moieties two benzene ring moieties. The molecule of FIG. 19b is derived from benzoquinone, pyridine, and acetylatone.

Larger fused-ring molecules employing at least one heterocyclic moieties are absolutely not limited to nitrogen heteroatoms. For example, FIGS. 19a-19b depict complex fused-ring molecules comprising sulfur-based aromatic heterocycle moieties and benzene ring moieties. The thiophene moiety is aromatic in each of these. Although tetrathiophene (FIG. 20a) and sulflower (FIG. 20b) are both oligothiophenes, some oligothiophenes are aromatic (for example tetrathiophene), while others (such as sulflower) are not aromatic.

Larger fused-ring molecules employing at least one heterocyclic moieties are absolutely not limited to single types of heteroatoms, or limited to heteroatoms from the same periodic table group:

FIGS. 21a-21c depict fused-ring molecules comprising moieties with nitrogen and oxygen heteroatoms.

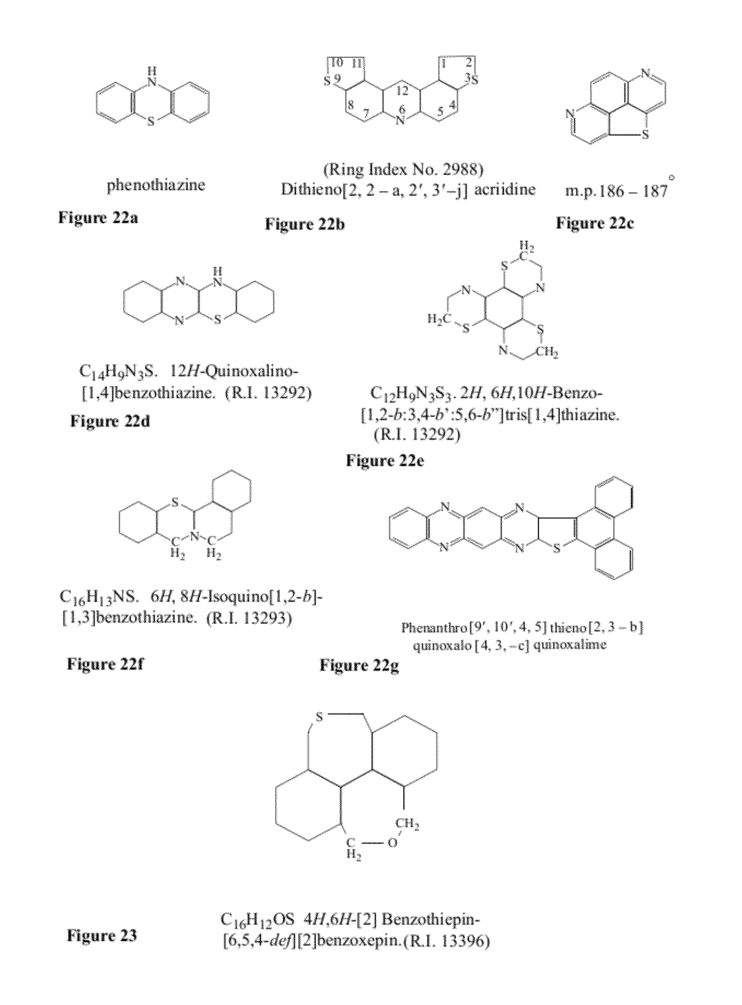

FIGS. 22a-22g depict fused-ring molecules comprising moieties with nitrogen and sulfur heteroatoms. (In FIG. 22f, the otherwise aromatic benzothiophene moiety is merged with aromatic isoquinoline in such a way that one of the carbon atoms of benzothiophene is replaced by nitrogen. The hydrogen-saturated carbons either side of the nitrogen atom interfere with molecular aromaticity.)

FIG. 23 depicts a fused-ring molecule comprising larger-ring heterocyclic moieties therein comprising oxygen and sulfur heteroatoms.

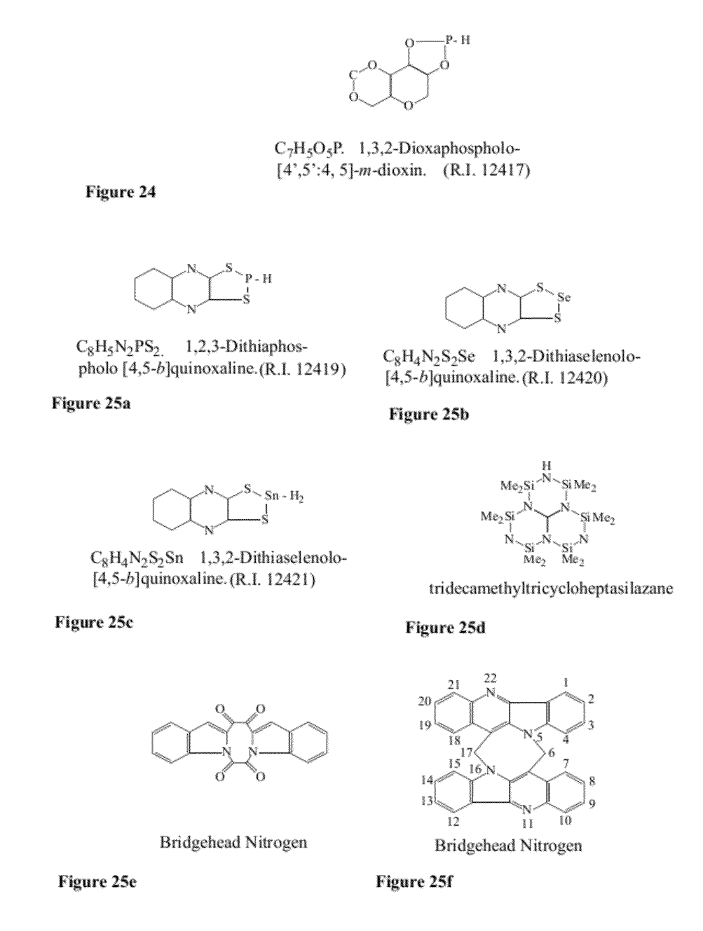

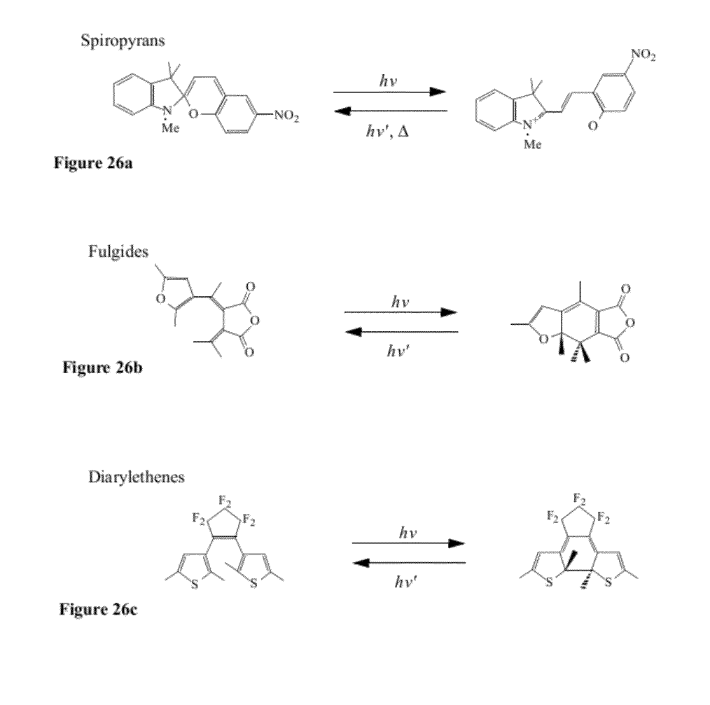

FIG. 24 depicts a fused-ring molecule comprising heterocyclic moieties therein comprising oxygen and phosphorus heteroatoms.

FIGS. 25a-25d depicts fused-ring molecules comprising heterocyclic moieties therein comprising nitrogen (Group 15) and other heteroatoms (Group 15 phosphorous; Group 16 sulfur, selenium; Group 14 tin, silicon).

FIGS. 25e-25f depict bridgehead nitrogen heteroatoms.

There are types of polycyclic molecules (other than polycyclic carbon compounds) that comprise one or more heteroatoms such as sulfur, phosphorus, oxygen, etc. Examples include polycyclic aromatic sulfur compounds (such as a thiaarane), polycyclic aromatic nitrogen compounds (such as an azaarane), polycyclic aromatic oxygen compounds (such as an oxaarane), etc. Those that are aromatic are known as Polycyclic Aromatic Compounds (“PAC”).

Such exhibits of various classes and example molecular structures could continue, and additional categories of cyclic molecules and supramolecular structures comprising them will be considered and incorporated into the invention, but via the examples thus far the following has been established:
Fused-ring molecules comprising a wide variety of heterocyclic moieties and heteroatoms are known. Further (although not considered here) there is a rich literature of the synthesis (and effectively the near design) of such molecules.
Heterocyclic moieties within larger fused-ring molecules offer properties that can be leveraged to provide signal input and output capabilities that differ from those available in polycyclic aromatic hydrocarbons.
Conceptually, heterocyclic moieties could provide variations in electrical, optical, magnetic, and chemionic behaviors so as to operate as differentiated components in a molecular electronics and/or chemionics system.

### 2.3. Clusters and Cages as Fused-Ring Molecules

Other forms of molecules that comprise multiple fused-rings are clusters and cases. These may be carbon-based, metal-based, or may comprise combinations of two or more of carbon, boron, phosphorus, sulfur, nitrogen, metals, or other elements. Many such molecules are aromatic, and some are doubly or triple aromatic by way of two or more of σ-, π-, and δ-electron systems within the cluster [9].

### 3. The Use of Ring Currents in Fused-Ring Molecules in the Invention

The invention gathers together the identified principle, structures, constructed components, etc. as well as those described in the remainder of the detailed description to create unique and novel systems and methods for designing, implementing, and integrating fused-ring ring current molecular electronics systems. The following are brought together from the extensive enablement discussion provided thus far:
The invention provides for a molecular electronics arrangement comprising at least one fused-ring molecule supporting and/or sustaining an induced ring current of electrons associated with the molecule.
The invention provides for a fused-ring molecule comprises a fused-ring (“condensed ring”) cyclic structure supports a plurality of ring currents of electrons associated with the molecule.
The aforementioned work of Clar and others that followed predict and demonstrates that vast non-symmetries in the relative strengths of ring current components within the mesh topology implied by the nucleus locations comprised by a fused-ring molecule. The invention provides for such non-symmetries in the strengths of ring current components invoke associated circuit design laws.
The invention provides for a fused-ring molecule comprising a fused-ring cyclic structure and disjoint aromatic sextet structures comprised by a fused-ring cyclic molecular are employed as ring current elements in a molecular electronics system.
The invention provides for at least one ring current flow within a ring plane defined by a ring-shaped interbonded collection of atoms comprised by the fused-ring molecule. [2]
The invention provides for at least one diatropic (a.k.a. “diamagnetic”) and/or paratropic (a.k.a. “paramagnetic”) ring, current employed within the fused-ring molecule.
The invention provides for at least one ring current flow outside a ring plane of the fused-ring molecule [2].
The invention provides for at least one ring current transported by □-electrons flows only on one side of a ring plane [2].
In an aspect of the invention, ring currents are induced by at least one time-varying magnetic field.
The invention provides for ring currents induced by at least two spatially-orthogonal time-varying magnetic fields.
The invention provides for at least one time-varying magnetic field and/or circularly-polarized laser pulse employed as a power source.
The invention provides for ring currents induced by at least two spatially-orthogonal circularly-polarized laser pulses.
The invention provides for additional degrees of control provided via the amplitude, wavelength, duration, and laser direction of polarization.
The invention provides for magnetic fields generated by the induced ring current. The direction of the circular polarization of the laser light controls the direction of an induced ring current.
The aforedescribed FIG. 5a depicts the induction of ring current from a circularly polarized laser pulse, and a subsequently magnetic field induced by the ring current. Since the direction of a circular electron current determines the direction of an induced magnetic field, the direction of the circular polarization of the laser light thus also controls the direction of the induced magnetic field. The invention provides for the direction of the circular polarization of the laser light to control the induced magnetic field.
Since some molecules (for example, azulene [3]) have differing ring current properties in excited states than in ground states, this laser pulse excitation can be used to modulate ring current properties (aromaticity, anti aromaticity, etc.). The invention provides for laser pulse excitation to modulate ring current properties.
Since some molecules (for example, again, azulene [3]) exhibit oscillating ring currents in excited states. Accordingly, the invention provides for molecular-scale oscillators that can be coupled via mesh currents in fused rings, induced magnetic fields, etc.).
The invention provides for excited states associated with laser pulses to be used to induce changed molecular conformation and other molecular rearrangements or topological feature changes to moieties within the molecule.
The invention provides for the use of laser pulse stimulation to invoke excited state chemistry, for example involving reactive intermediates.
The invention provides for the use of laser pulse stimulation to invoke excited state photon emission at a wavelength differing from the laser.
The invention provides for the use of laser pulse stimulation to induce ring currents with different flow topologies than would be produced by time-varying magnetic fields.
The invention provides for a fused-ring molecule to comprise an inorganic ring structure, cluster structure, and/or cage structure, for example comprising one or more atoms of sulfur, phosphorus, boron, etc.
The invention provides for a fused-ring molecule that is non-planar.
The invention provides for a fused-ring molecule comprising a conjugated and/or hyperconjugated compound, ring, moiety, or functional group.
In another aspect of the invention, a fused-ring molecule comprises a strained ring, moiety, or functional group.
In another aspect of the invention, the fused-ring molecule comprises a strained unconjugated ring which as a result of the strain supports and/or sustains a ring current (“strained ring current”). [2]
In another aspect of the invention, at least one ring current flows within an atom comprised by the fused-ring molecule. [2]
In another aspect of the invention, at least one ring current is split at a moiety comprised by the fused-ring molecule. [2]
In an embodiment, the interacting ring currents are also influenced by other process and structures responsive to signal inputs (photonic, electrical, magnetic, chemical, etc.). The mutual interaction among ring currents in a fused-ring molecule is used to create an electrical structure similar to a mesh-topology electrical circuit.
In an embodiment, at least one ring current induces a process or phenomena (photonic, optical, electrical, magnetic, chemical, etc.) which can be measured or which can influence an external entity, providing the role of a signal output.
In an embodiment, the new framework and associated technology uses properties of one or more cyclic moieties or other structures to influence affairs at one or more of at least another cyclic moiety or other structure within a common fused-ring molecule.
In an embodiment, fused-ring molecules are architected so that various ring currents (diatropic, paratropic, strain, homoaromatic) can be introduced and traded-off to deliver attributes advantageous to the invention and its applications.
In an embodiment, the presence of heteroatoms (non-carbon) in cyclic moieties or other structures creates an environment for design-parameter variation in the behavior of ring currents and thus the resultant “mesh” currents.
In an embodiment of the invention, the heterocyclic moieties can be aromatic.
In another aspect of the invention, a fused-ring molecule or fused-ring cyclic structure comprises at least one bridgehead heteroatom. For example, nitrogen and oxygen offer lone pairs that can hybridize for enlistment in ring currents.
In an embodiment, the structure of a fused-ring molecule can be changed by an external process, resulting in a change in at least one ring current.
In an embodiment, the conformity of a fused-ring molecule can be changed by an external process, resulting in a change in at least one ring current.
At least one of the cyclic moieties or other structures is used to receive one or more signal inputs (photonic, chemical, magnetic, electrical, etc.), and at least one of the cyclic moieties or other structures is used to provide one or more signal outputs (photonic, chemical, magnetic, electrical, etc.).
Outputs can be rendered as inter-molecular coupling, non-proximal measurements, chemical reactions, molecular rearrangement, signal transduction, change in optical properties, excited state, optical emission, etc.
In one aspect of the invention, heterocyclic aromatic ring moieties within larger fused-ring molecules are used to create structural variations with ring current properties that differ from the ring currents in polycyclic aromatic hydrocarbons.
In another aspect of the invention, heterocyclic aromatic ring moieties within larger fused-ring molecules are leveraged to provide signal input and output capabilities that differ from those available in polycyclic aromatic hydrocarbons.
In an embodiment of the invention, heterocyclic moieties are used to provide variations in electrical, optical, magnetic, and chemionic behaviors, said variation as compared to those provided by benzene-ring moieties, so as to operate as differentiated components in a molecular electronics and/or chemionics system.
The invention provides for a magnetic deshielding effect within the fused-ring molecule employed in determining or influencing a ring current.
The invention provides for a magnetic deshielding effect within the fused-ring molecule icreated by steric interactions among crowded protons. [10]
In another aspect of the invention, a polar effect within the fused-ring molecule is employed in determining or influencing a ring current.
In another aspect of the invention, the fused-ring molecule comprises at least one aromatic system in a first plane and at least one other aromatic system in a second plane orthogonal to the first plane.[4]
In another aspect of the invention, the fused-ring molecule comprises a closed 3-dimensional form topologically embeddable in the surface of a torus and a surface current (for example, “sphere current”) is used.
In another aspect of the invention, the fused-ring molecule comprises a closed 3-dimensional form topologically embeddable in the surface of a sphere and a surface current (for example, “sphere current”) is used.
In another aspect of the invention, the fused-ring molecule comprises at least one cyclic structure in a first plane and at least one other cyclic structure in a second plane orthogonal to the first plane.
In another aspect of the invention, the fused-ring molecule comprises at least one aromatic system in a first plane and at least one other aromatic system in a second plane orthogonal to the first plane. [4]
In another aspect of the invention, the fused-ring molecule comprises multiple aromaticity systems from the collection of the n-bond system, σ-bond system, and/or δ-bond system. [10]
The invention provides for at least one fused-ring structure comprising at least one polycyclic aromatic sulfur compound polycyclic aromatic nitrogen compound, and/or polycyclic aromatic oxygen structure.

More on these and related aspects of the invention will be provided in the remainder of this specification.

### 4. Signal Input Aspects of the Invention

Using the various properties and arrangements described thus far, the invention provides a wide range of possible signal input processes that can be used to influence the size and other aspects of induced ring currents in a fused-ring molecule. Various embodiments of the invention can comprise one or more signal inputs of one or more of the following types:
In an embodiment, a ring current within a fused-ring molecule is affected by an electrical phenomena signal input process, for example, an electric field or change in molecular polarization;
In an embodiment, a ring structure within a fused-ring molecule is affected by a photonic phenomena signal input process, for example, through the invocation of at least one excited state or at least one photo-induced molecular rearrangement;
In an embodiment, a ring current within a fused-ring molecule is affected by a chemical phenomena signal input process, for example through the invocation of at least one photo-induced molecular rearrangement;
In an embodiment, a ring current within a fused-ring molecule is affected by a magnetic phenomena signal input process, for example perturbing or inducing an individual ring current.
   Further attention is directed to these in the subsections below and in subsequent portions of the specification.

### 4.1 Photon-Input Processes

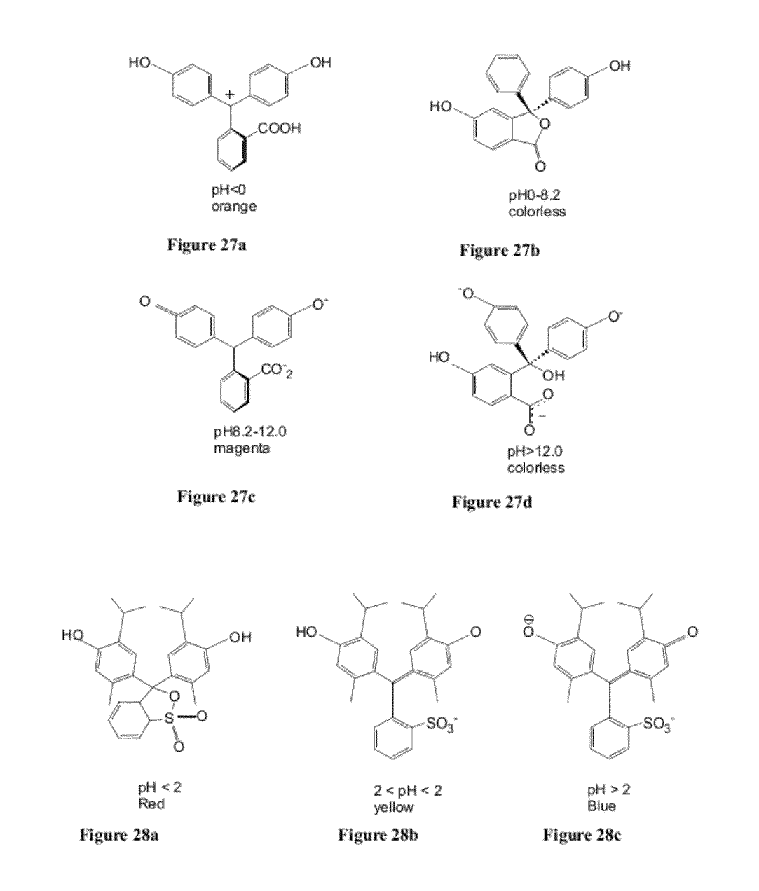

A first example of a photon-input process provided for by the invention is one involving photochromism [11], is now provided to demonstrate ways in which the latter two conceptual principles may be realized. More specifically, the spiropyrans (FIG. 27a), fulides (FIG. 27b), and diarylethenes (FIG. 27c) are among a group of fused-ring heterocyclic compounds wherein at least one ring can open and close in response to the application of light of specific wavelengths, resulting in differing isomers. In the case of fulides (FIG. 27b) and diarylethenes (FIG. 27c), the topologically-central ring of the entire fused-ring molecule opens and closes under selected photon stimulation. As a result, the entire topology of the fused-ring molecule (and resulting distribution of ring currents, as well as some chemical properties) may be optically modulated. Note in the case of diarlylethenes (FIG. 27c) two of the unchanged moieties are aromatic (thiophene, discussed earlier) and the closed form of the modulated ring is an (aromatic) benzene ring moiety. Many fulides and diarylethenes are thermally stable, so they are only controlled by photons. For the class of diarlylethenes known as diarlylethenes:
Methyl groups attached to the thiophenes prevent oxidation of the closed ring form;
The overall molecular shape undergoes only minor changes as the rings opens and closes, allowing their incorporation into larger structures (crystals being one example) as operative photochromic molecules;
The isomers have differing absorption spectra, refractive indices, dielectric constants, and oxidation-reduction potentials;
The closed-ring isomer, in addition to linking the two near edges of the thiophene molecules, also shifts the p-orbital electrons to form double bonds that provide a conjugated bond path across the entire molecule to functional groups terminating on the thiophene molecules, permitting electronic communications between the functional groups, a trait that amounts to an optically-controlled molecular electrical switch,
Larger structures, such as crown ethers, may be attached to diarlylethenes.

The above discussion provides only a simple motivating example. There are an extensive range of compounds and moieties with photo-modulated structural properties that can control the affairs of ring currents.

In an embodiment, the invention provides for the use photochromic compounds as transducer elements within fused-ring molecular electronic systems employing operation on and by molecular ring currents. In an embodiment, the invention provides for the use photochromic compounds as memory elements within fused-ring molecular electronic systems employing operation on and by molecular ring currents. In an embodiment, the invention provides for the use photochromic compounds as R-S flip-flop elements within fused-ring molecular electronic systems employing operation on and by molecular ring currents. In an embodiment the invention provides for the use photochromic compounds as nanoscale moving mechanical elements within fused-ring molecular electronic systems additionally employing operation on and by molecular ring currents.

Another example is the use of a photonic process to create an excited state. Such an excited state can be used to change ring current properties (for example, to modulate between aromaticity, antiaromaticity, nonaromicity, etc.) Alternatively or in conjunction, such an excited state can be used to induce conformational changes as a result of molecular rearrangements that affect, for example, the ring topology of the fused-ring molecule. Alternatively or in conjunction, such an excited state can be used for chemical reaction purposes.

### 4.2 Chemical Input Processes

A first example of a photon-input process provided for by the invention is that of ring topology of the fused-ring molecule. As a couple of initial examples, the pH dependence of the molecular topology of two common pH indicators is considered.

First, FIGS. 27a-27d depict the pH indicator molecule phenolphthalein in various pH conditions. The phenolphthalein molecule of FIG. 27b (and in fact the synthesis of phenolphthalein) can be seen as involving a condensation of phthalic anhydride with two phenol groups. Phthalic anhydride itself is a fused molecule comprising a furan (resembling maelic anhydride) and a benzene ring. Here, discussion is directed to the two colorless pH regimes (pH<0-8.2 and pH>12.0) rather than the more well-known colored ions occurring for pH 8.2-12.0 (magenta) FIG. 27c and pH<0 (orange) FIG. 27a. In FIG. 27b, the phenolphthalein molecule comprises a fused molecule comprising a furan ring (resembling maleic anhydride) and a benzene ring. This fused molecule provides a setting for two meshed ring currents, a venue for each of the furan ring and the benzene ring. Under other pH conditions (FIGS. 27a, 27c, and 27d) the furan ring disappears, removing the furan ring current venue. In each case the remaining benzene ring remains orthogonal to the two phenol elements. Thus the ring current in the “phthalic anhydride” moiety is switched on and off by pH changes.

Next, “Thymol blue” (thymolsulphonephthalein) is also used as a pH indicator; it makes color transitions from red to yellow at pH 1.2-2.8 and from yellow to blue at pH 8.0-9.6. FIGS. 28a-28c depict the thymol blue (thymolsulphonephthalein) molecule in various pH conditions. For the example, the two pH regimes pH<2 (FIG. 28a) and pH>2 (FIGS. 28b-c) are of interest. The thymol blue (thymolsulphonephthalein) molecule at pH<2 comprises a fused-ring moiety with a 1,2-oxathiole ring fused with a benzene ring. This fused molecule provides a setting for two meshed ring currents, a venue for each of the 1,2-oxathiole ring and the benzene ring. Under pH>2 conditions (FIG. 28b and FIG. 28c) the 1,2-oxathiole ring disappears (the sulfone becomes a sulfite), thus removing the 1,2-oxathiole ring current venue. Hence the ring current in the “1,2-oxathiole ring” moiety is switched on and off by pH changes.

Accordingly, such approaches provide control of the existence of a molecular ring as a function of pH. In the case of phenolphthalein, a fused-ring molecule is actively involved center-stage. This general principle can be adapted to create similar types of reversible and non-reversible molecular topology and geometry modulations affecting ring currents in other types of fused-ring molecules, and further devised so that such molecular topology and geometry modulations are responsive to one or more chemical conditions including or other than ranges of pH.

As a different example, a chemical input process can invoke a chemical reaction that creates, destroys, or alters one or more rings or ring-fusions of a fused ring molecule. This change in molecular topology can be used to affect ring currents in the fused-ring molecule.

As yet another example, a chemical input process can be used to change or replace a functional group that clamps resonant modes to a particular fixed conjugation structure. This change can be used to affect ring currents in the fused-ring molecule.

As yet another example, a chemical input process can be used to change the average distributions of tautomerisms involving a fused-ring molecule in such a way to affect ring currents in the fused-ring molecule.

As yet another example, a chemical input process can be used to change the charge distributions of a fused-ring molecule in such a way to affect ring currents in the fused-ring molecule, for example, changing the polarity of the molecule.

In an embodiment, chemical input processes employed by the invention can comprise the use of a collection of synthons.

### 4.3 Magnetic Input Processes

Nonplanar molecular structure of multiple-ring molecules can be used to create additional magnetic stimulus channels.

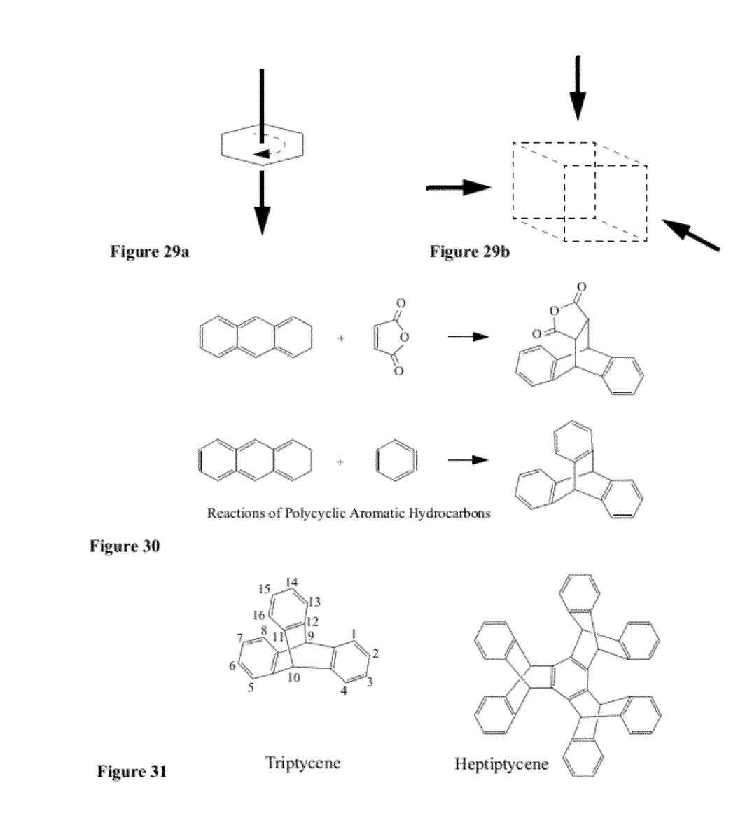

FIG. 29a shows a representation of the one-dimension time-varying magnetic stimulus used to induce ring currents that was depicted earlier in FIG. 4. FIG. 29b depicts three orthogonal magnetic field directs that can be used for “powering” (inducing ring currents) and/or signal inputs and/or signal outputs. These are useful for molecular and supramolecular fused-ring systems that are nonplanar and are provided for by the invention.

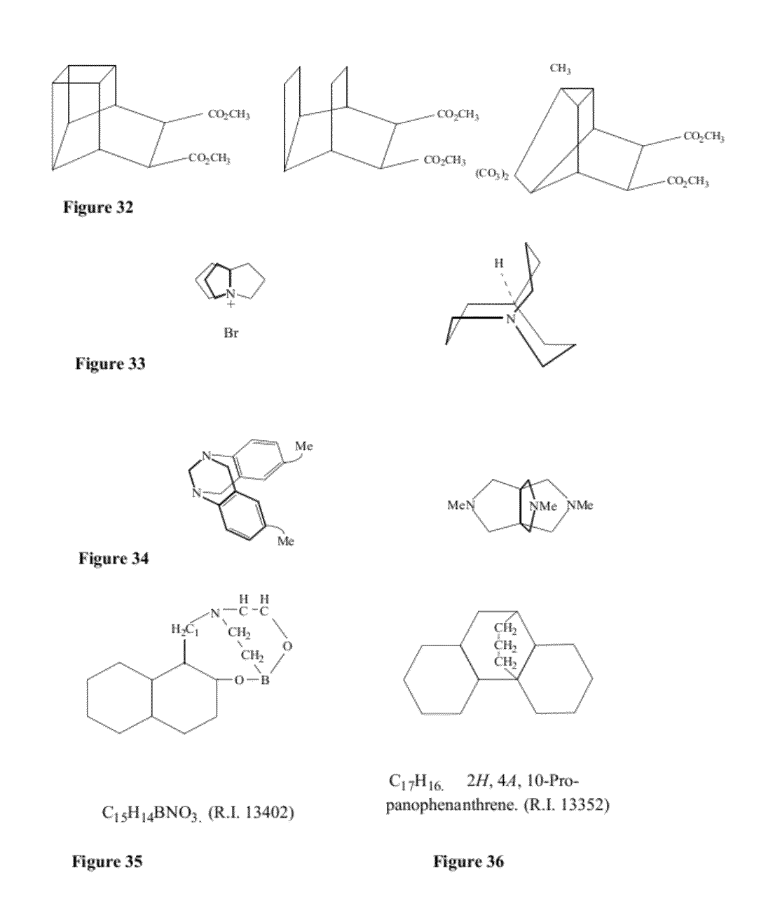

FIGS. 30-34 depict molecular fused-ring systems that are nonplanar. FIGS. 33 and 34 depict bridge structures FIGS. 35-36 depict bridge structures. Many bridge structures give rise to nonplanar ring molecular moieties. In some situations, one or more ring moieties may be spatially-orthogonal to other ring moieties. In an embodiment, spatially-orthogonal magnetic fields are aligned so as to render projections onto ring moieties separated by a dihedral angle.

In another aspect of the invention, a fused-ring molecule comprises a bridge. In related aspects of the invention, a fused-ring molecule comprises a bridged aromatic moiety or a polyvalent bridge.

The invention provides for the use of at least two spatially-orthogonal magnetic fields, as described above in conjunction with FIG. 34b, to be used to stimulate ring currents. The invention provides for the use of at least two spatially-orthogonal magnetic fields to be used to stimulate ring currents wherein one is “powering” and another is used for providing signal input. The invention provides for the use of at least two spatially-orthogonal magnetic fields to be used to stimulate ring currents wherein one is “powering” and another is used for measuring signal output. The invention provides for the use of at least three spatially-orthogonal magnetic fields to be used to stimulate ring currents wherein one is “powering,” another is used for providing signal input, and another is used for measuring signal output. The invention further provides for at least two ring moieties to be magnetically coupled using a magnetic field direction that is spatially-orthogonal to a “powering” or stimulating magnetic field.

### 4.4 Circularly-Polarized Laser-Pulse Input Processes

In analogy with the section immediately above, the invention provides for the use of at least two circularly-polarized laser-pulse sources. These can have different characteristics (wavelength, circular direction, pulse duration, amplitude, etc.) and/or can be spatially-orthogonal. The invention provides for the use of at least two spatially-orthogonal circularly-polarized laser-pulse sources to be used to stimulate ring currents wherein one is “powering” and another is used for providing signal input. The invention provides for the use of at least three spatially-orthogonal circularly-polarized laser-pulse sources to be used to stimulate ring currents wherein one is “powering,” and the other two are used for providing signal inputs.

### 5. Mesh Current Molecular Electronic Circuits

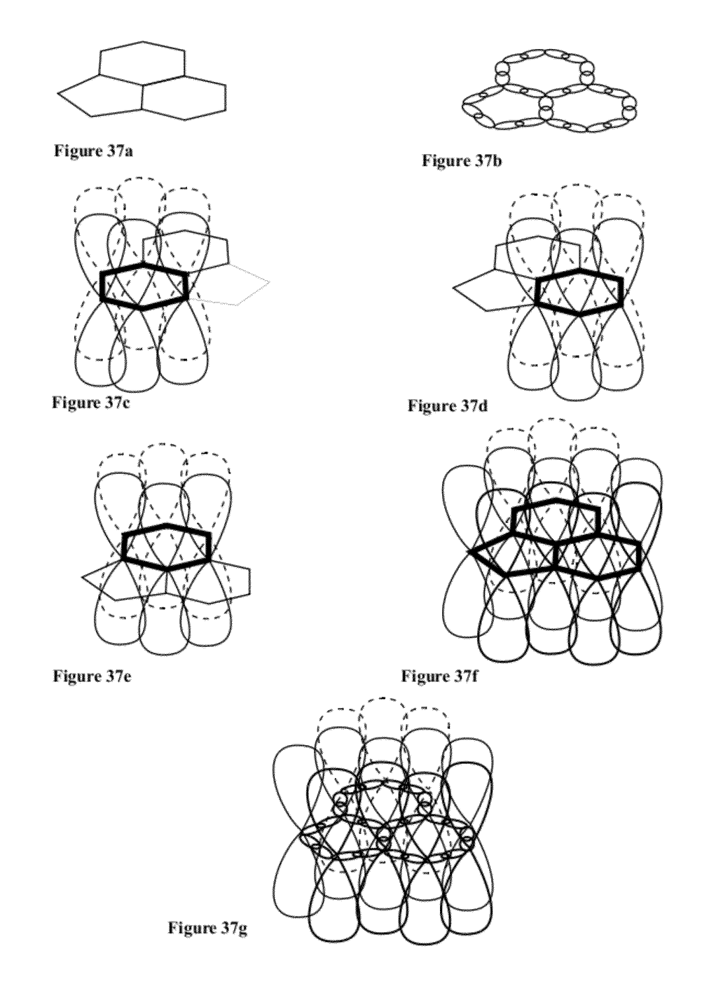

Next attention is directed to more detailed consideration of π-cloud ring currents in fused-rings and their metaphor with the mesh current operation of conventional electronic circuitry. To begin FIG. 37a depicts a schematic representation of a fused-ring molecule. FIG. 37b depicts overlapping σ-orbitals of the fused-ring molecule depicted the schematic representation of FIG. 37a.

FIGS. 37c-37e depict the overlapping p-orbitals for each of the individual ring moieties in fused-ring molecule depicted the schematic representation of FIG. 37a.

FIG. 37f depicts the overlapping p-orbitals for all of the ring moieties in fused-ring molecule depicted the schematic representation of FIG. 37a. FIG. 37g depicts the overlapping p-orbitals of FIG. 37f with the overlapping σ-orbitals of FIG. 37b.

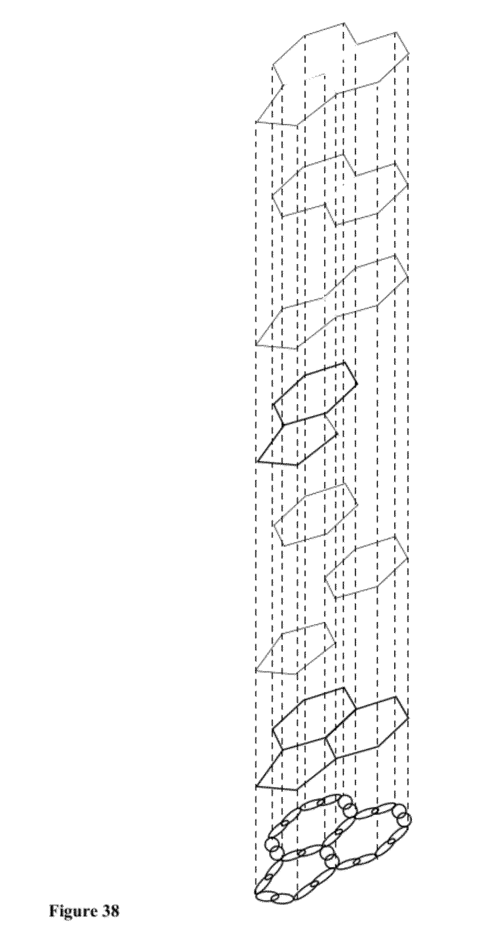

FIG. 38 depicts, from bottom to top, the overlapping σ-orbitals of FIG. 37b, its schematic representation of FIG. 37a, each of three ring current components confined to each of the ring moieties, three pair-wise perimeter internal ring currents between pairs of ring moieties, and the outer perimeter ring current. Because of Kirkoff's current laws (or through use of other mathematical arguments), the ring currents obey linear summation rules and some of these seven ring current components can be expressed in terms of others. Cut-set analysis or other mathematical tools can be used to identify a (typically non-unique) set of “basis” ring currents. In polycyclic aromatic hydrocarbons, ring currents may be calculated by graph theory representations of molecular topology [12]

$$\frac{{I}_{i}}{{I}_{o}} = 18 \frac{{S}_{i}}{{S}_{o}} {\sum }_{j = 1}^{n} \frac{{P}_{G - {Γ}_{i}} ( {X}_{j} )}{{P}_{G}^{l} ( {X}_{j} )} \qquad [ 1 ]$$

This type of analysis may be adapted to other fused-ring molecules and fused-ring supramolecular structures.

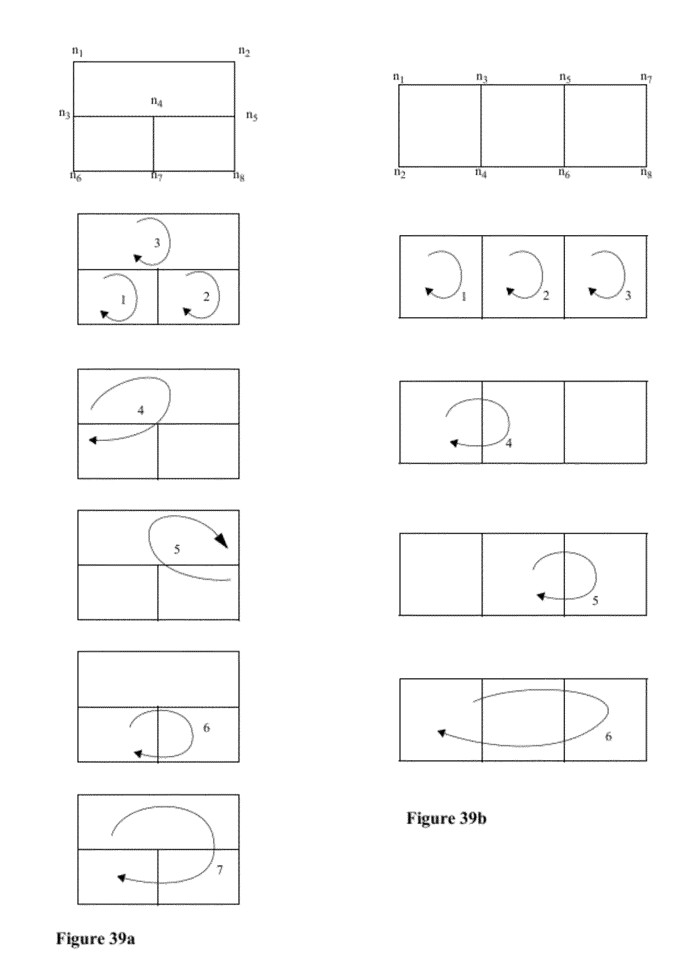

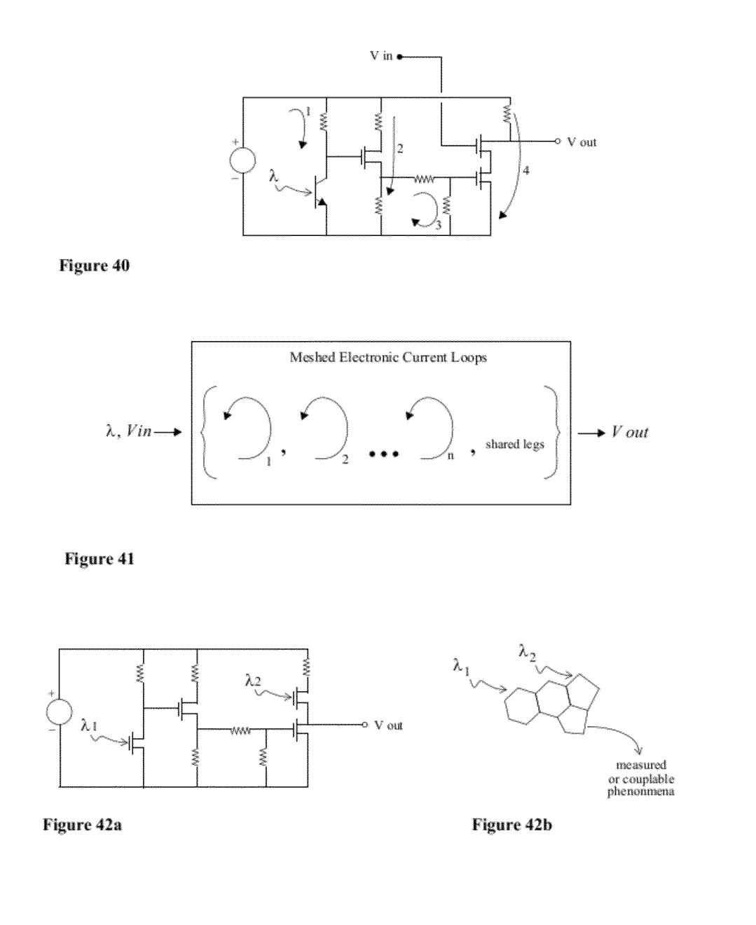

FIGS. 39a and 39b depict mesh current components for two abstract fused-ring structures. The collection of mesh current components of FIG. 39a can be viewed as isomorphic to the collection of ring current components of FIG. 38. This forms the basis for analogous design and operation of fused-ring ring current meshes as compared to traditional electronic circuits. Further as to this, FIG. 40 shows an electronic circuit comprising a photonic input, a voltage input and a voltage output. This can be abstracted as FIG. 41 depicts, the abstraction comprising a photonic input, a voltage input a voltage output, and a plurality of internal meshed current loops.

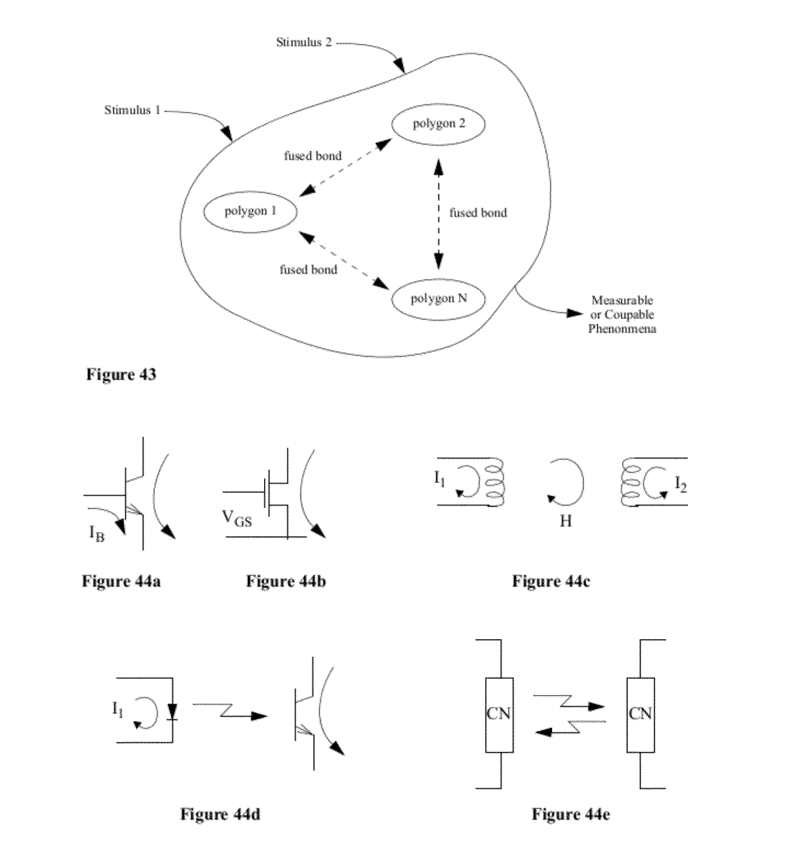

FIG. 42a depicts another electronic circuit comprising two photonic inputs and a voltage output. FIG. 42b depicts a molecular electronic circuit comprising two photonic inputs and a measurable or couplable phenomena output. This type of analogy provides at least one conceptual framework for the invention. For example, at a higher level of abstraction and generality provided by the systems and methods of the invention, FIG. 43 depicts an abstraction of the molecular electronic circuit of FIG. 42b. The polygons are ring moieties of the molecular ring current electronic system. The invention provides for extending this abstraction to arbitrary numbers and types of inputs, outputs, physical linking, and interactions among molecular moieties.

FIGS. 44a-44e depicts various coupling mechanisms between electronic circuit elements involving at least one current. FIG. 44a extends this to optical linking between carbon nanotube FETs as provided for in pending U.S. patent application Ser. Nos. 12/033,212 and 12/025,562. The invention provides for analogous coupling among molecular moieties in a fused-ring molecular ring-current electronic system. The invention provides for at least two ring moieties to be magnetically coupled. The invention provides for at least two ring moieties to be unidirectionally optically coupled. The invention provides for at least one pair of ring moieties to be bidirectionally optically coupled. The invention provides for at least two ring moieties to be mutually optically coupled.

### 6. Supramolecular Structures

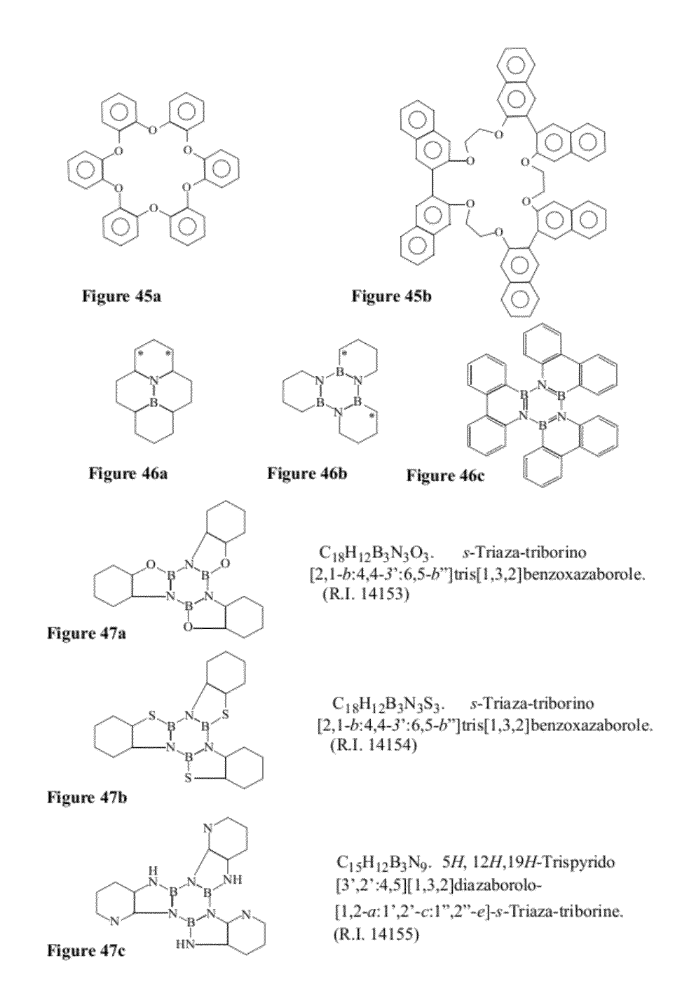

The invention provides for use of supramolecular structures comprising macrocyclic rings for use in ring-current molecular electronics. The invention provides for supramolecular structures to provide additional features and/or functionality of use in ring-current molecular electronics. FIGS. 45a-45b depict crown ethers fused with aromatic ring compounds. Crown ethers can be used to form complexes comprising metal ions or other materials. Such complexes have valuable electronic, photonic, and chemical properties that can perform functions useful in ring-current molecular electronic systems. The oxygen atoms in a crown ether can be replaced with sulfur or other atoms to produce other types of crown compounds (for example, aza-crowns). The invention provides for the use of crown compound complexes to provide additional features and/or functionality of use in ring-current molecular electronic systems.

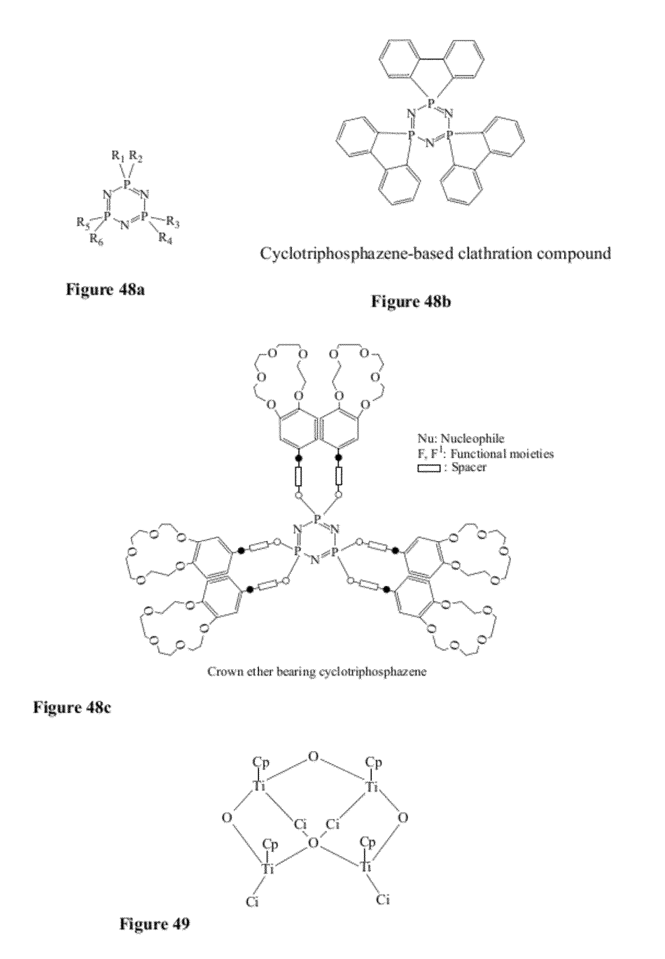

The invention provides for nitrogen-boron fused-ring compounds, nitrogen-phosphorus fused-ring compounds, borane compounds, carboborane compounds, carbocyclic cage compounds, and cluster compounds to be provide rings supporting ring currents. Such molecules provide a broader range of 2D and 3D topologies as well as additional features and/or functionality of use in ring-current molecular electronic systems. FIGS. 46a-46c and 47a-47c depict nitrogen-boron fused-ring compounds. FIGS. 48a-48c depict nitrogen-phosphorus fused-ring compounds. FIG. 49 depicts a cluster compound. All of these types of structures have many examples supporting ring currents and which can be linked to other types of molecules. Thus, these types of structures simply provide the invention with a yet wider pallet from which to design and construct molecular electyronics circuits employing ring current electronics. Additionally cages and clusters provide 2D and 3D structures that can be used for spatially-orthognal signal input, ring current excitation, etc. Accordingly, the invention provides for nitrogen-boron fused-ring compounds, nitrogen-phosphorus fused-ring compounds, borane compounds, carboborane compounds, cage compounds, and cluster compounds to provide additional features and/or functionality of use in ring-current molecular electronic systems. Additionally, sulfur compounds such as circulene and sulflower, also provided for by the invention, comprises a nested cyclic macroscopic structure, geodesic polyarene structures, etc. that are useful building blocks for ring-current molecular electronic systems. Further, in another aspect of the invention, a fused-ring molecule comprises a helicene supporting ring currents. The helicene molecular structure provides a framework for self-influencing effects in adjacent winds of the helix, as well as recognized special spectral and optical properties of that can be used to expand the input and output pallet of a ring-current molecular electronic system. In another aspect of the invention, a fused-ring molecule comprises an propellane, for example, as shown in FIG. 33.

### 6.1 Use of Ring Currents of Porphyrin and Related Structures

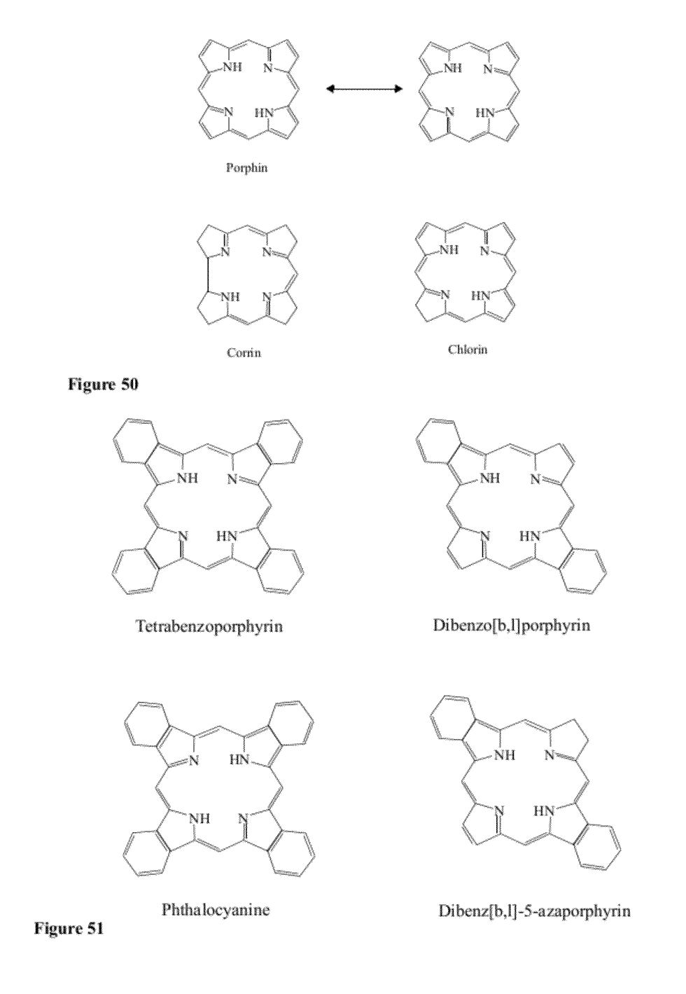

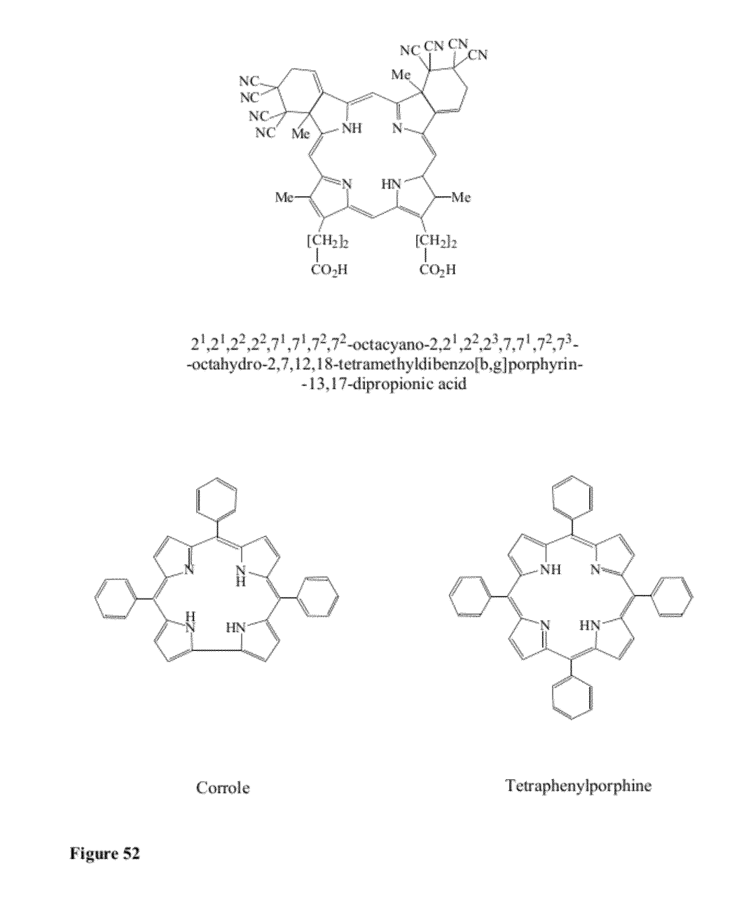

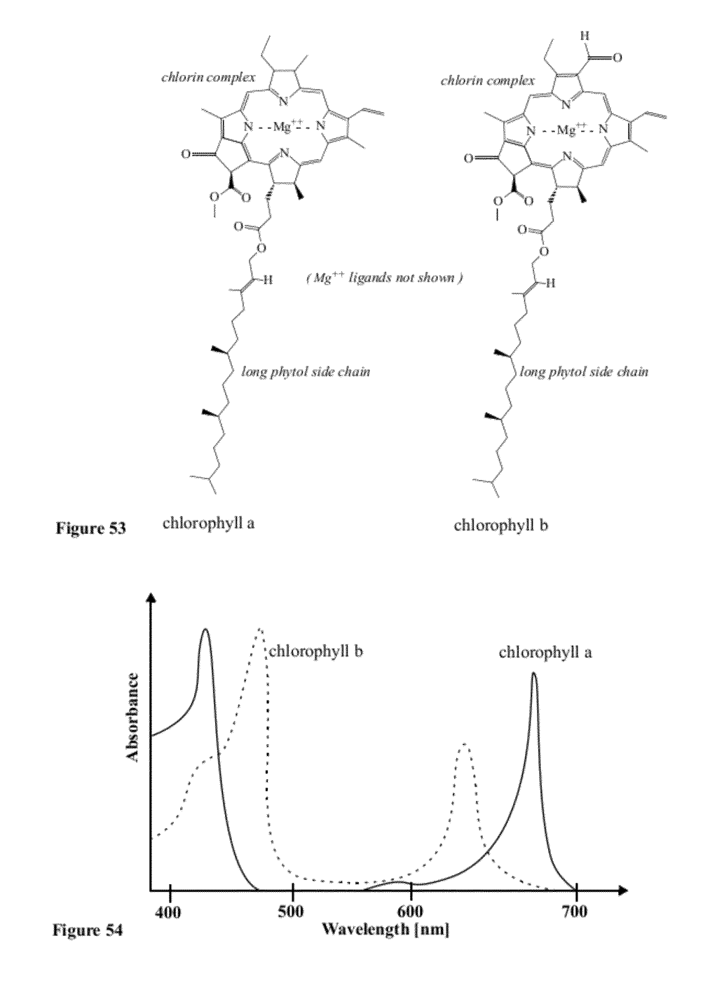

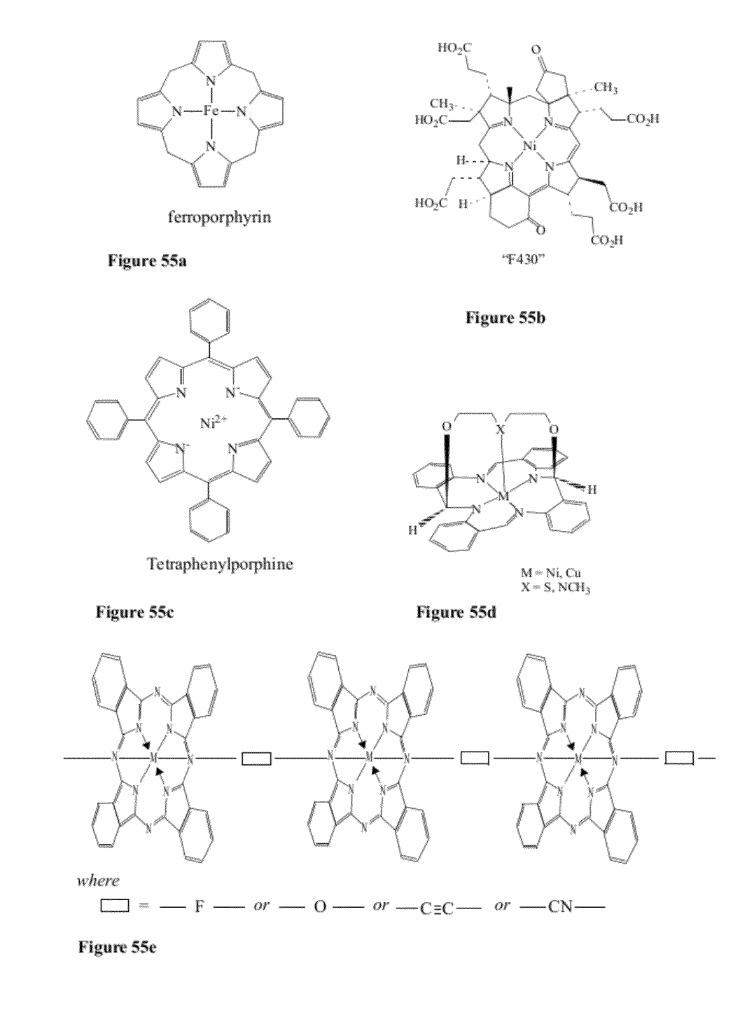

Porphyrin and related structures such as a phthalocyanine structure, tetrapyrrole structure, cyclic polypyrrole structures comprise a plurality of molecular rings in nested ring arrangements and support ring currents. They are also readily augmented with functional groups that influence their ring current, catalytic, and photonic properties, and can be readily incorporated into very large molecules. Such molecules are typically aromatic and provide a broad range of additional topologies as well as additional features and/or functionality of use in ring-current molecular electronic systems. FIGS. 50-52 depict some example porphyrins and related compounds. As described in the next section, Porphyrins form complexes with metals and other ions, and many have important photoreactive, photocatalytic, and photoelectric properties. One type of very important porphyrin is chlorophyll, the centerpiece of biological photosynthesis in plants. FIG. 53 depict Chlorophyll a and Chlorophyll b; these have notable differences in their photonic spectra, as depicted in FIG. 54, resulting from the slight differences in functional groups. Functional groups attached to porphyrins can be thus be design so to provide for multiple channels of wavelength multiplexed input signals into a fused-ring ring current environment. Accordingly, the invention provides for a fused-ring molecule to comprise a macrocyclic structure such as a phthalocyanine structure, porphyrin structure, tetrapyrrole structure, cyclic polypyrrole structure, etc. In that augmented/enlarged porphyrins have many attractive properties [13] useful for ring current molecular electronics as described thus far, the invention provides for a fused-ring molecule to comprise an enlarged porphyrin.

### 6.2 Use of Porphyrin Complexes, Metallocenes, Sandwich Compounds, and Other Complexes

Porphyrin, cyclopentadienyl anions, crown compounds, cyclodextrens, other macrocyclic compounds, and related structures form complexes comprising metal ions or other materials. Here crown compounds comprise but not limited to crown ethers, crown esters, aza-crowns, thia-crowns, selena-crowns, organosilicon crowns, mixed amine-ether crowns, etc. In another aspect of the invention, a fused-ring molecule comprises a multidentate macrocyclic structure. In another aspect of the invention, a fused-ring molecule comprises a cyclophane.

Many of these support ring currents and many are aromatic. Such complexes typically comprise rings as well as additional features and/or functionality of use in ring-current molecular electronic systems. Further, such complexes have valuable electronic, photonic, and chemical properties that can perform functions useful in ring-current molecular electronic systems. Transition metal complexes offer rich properties due the complexities of the d-shell orbital and associated processes. Other types of complexes relevant to the invention include but are not limited to metallocenes and other types of sandwich and half-sandwich molecular structures. Half-sandwich molecular structures are employed in charge-transfer complexes which are described later in the detailed description. Metallocenes and other types of sandwich and half-sandwich molecular structures can also be used to create polymer structures useful for the invention. Accordingly, the invention provides for porphyrin complexes, macrocyclic complexes, crown complexes, metallocenes, sandwich compounds, and other and related complexes and structures to be used in ring-current molecular electronics.

FIGS. 55a-55c depict some example metallic porphyrin complexes. FIG. 55d depicts a metallic porphyrin complex comprising a bridge that additionally provides field influences on the complexifying metal ion. FIG. 55e depicts polymers that can be created from planar metallic porphyrin complexes. The invention provides for the use of porphyrin and related structures and for use of metallic porphyrin complexes to provide additional features and/or functionality of use in ring-current molecular electronic systems.

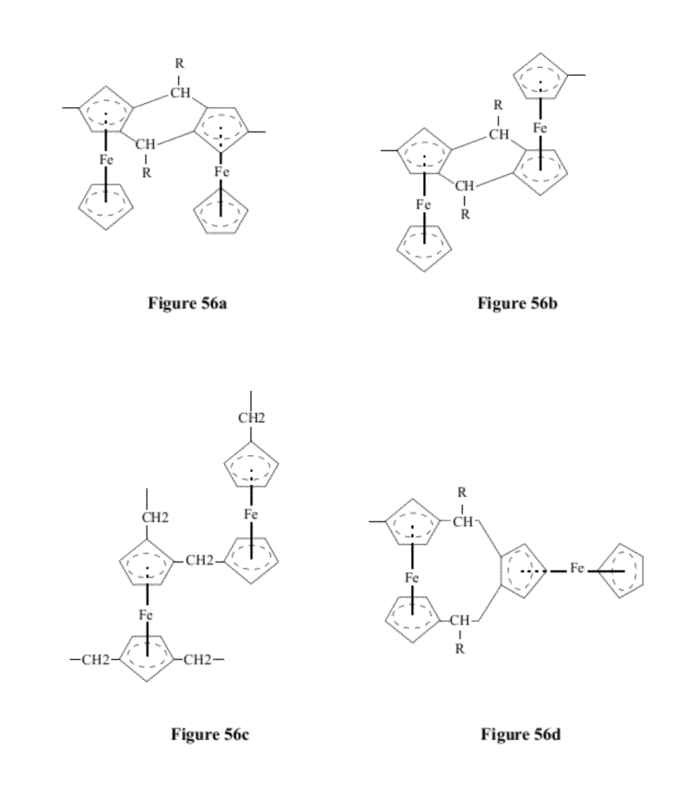

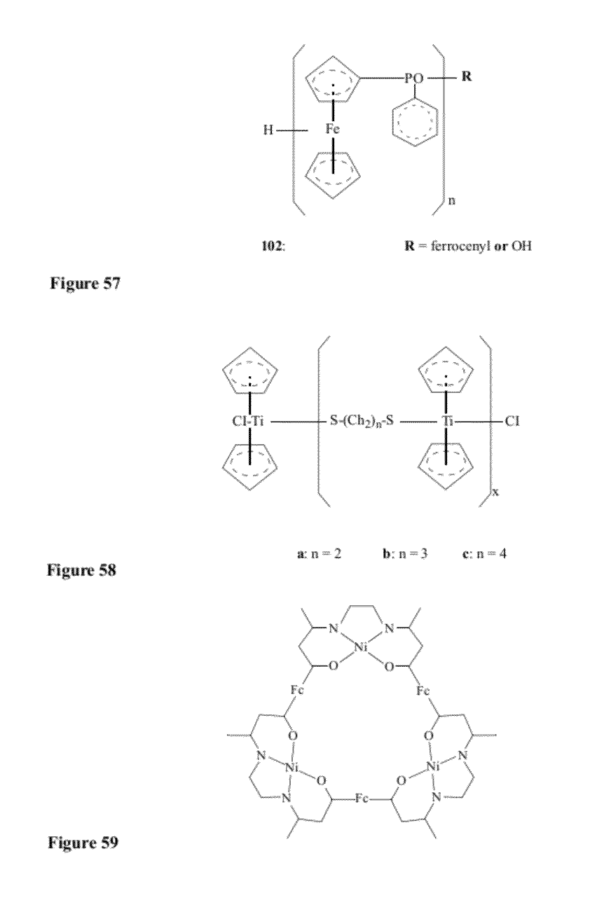

Metallocenes can be used to create larger structures as well as polymer chains. In an embodiment, metallocenes are used to coupled fused-ring molecules. In an embodiment, metallocenes are electrically coupled with other ring-molecules. In an embodiment, the metallocenes are magnetically coupled with other ring-molecules. In an embodiment, the metallocenes are optically coupled with other ring-molecules. Accordingly, the invention provides for metallocene structures to be used in ring-current molecular electronics, and to provide additional features and/or functionality of use in ring-current molecular electronic systems. One type of relevant metallocene structures are the ferrocenes. FIGS. 56a-56c depict example ferrocenes. FIG. 57 depicts an example ferrocene polymer. FIG. 58 depicts an Ti-based metallocene polymer. Metallocenes of interest to the invention include multi-metal composition; for example FIG. 59 depicts a ring Ni-based and Fe-based metallocene. Transition metal metallocenes offer rich properties due the complexities of the d-shell orbital and associated processes.

In another aspect of the invention, a fused-ring molecule comprises a complex involving a calixarene. In a related aspect of the invention, a fused-ring molecule comprises an cyclic chelate.

### 6.3 Use of Host-Guest Structures

The invention provides for the use of host-guest structures and chemistry in fused-ring molecule ring current electronics. Host molecules can be used to shield a guest molecule to external stimuli. Variable-structure Host molecules can be used to selectively shield or expose a guest molecule to external stimuli. Host molecules can be used to process external stimuli and present to a guest molecule via magnetic, electric field, and/or optical coupling.

In an aspect of the invention, a fused-ring molecule comprises a cyclophane, calixarene, and/or a calixarene structure.

### 7. Use of Polymer Structures

Polymer chains may be used to expand the physical size and provide repeating structures. Polymer chains can also be used as a fabricating substrate for fused-ruing ring current molecular electronics. Accordingly, the invention provides for a fused-ring macromolecule to comprise at least one polymer, block polymer, coblock polymer, cross-linked polymer etc. Additionally, the invention provides for a fused-ring molecule to be used as a monomer or other element within a macromolecule comprising at least one polymer, block polymer, coblock polymer, cross-linked polymer etc.

Attention is again directed FIGS. 55e, 57, and 58, each discussed earlier and which depicts polymers that can be created from planar metallic complexes. The invention provides for planar metallic complex polymers to be used in ring-current molecular electronics, and to provide additional features and/or functionality of use in ring-current molecular electronic systems. In an embodiment, the planar metallic complexes are magnetically coupled in a chain. In an embodiment, the planar metallic complexes are electrically coupled by functional groups linking them. In an embodiment, the planar metallic porphyrin complexes are coupled by electric fields. In an embodiment, the planar metallic porphyrin complexes are optically coupled.

The polymer chain provides a means of implementing elements that behave in a manner similar to distributed parameter passive and active electronics elements (lossy transmission lines, distributed transistors, etc.). Accordingly, the invention provides for metallic complex or fused-ring molecule polymer chains to be used to approximate an idealized electronic distributed-parameter component.

### 8. Use of Functional Groups and Charge Transfer Complexes to Influence a π-Cloud

Functional groups are known to lead to unexpected acid-base properties of aromatic molecules. (see for example http://209.85.173.132/search?g=cache:73HyNcTcgWEJ:wiz2.pharm.wayne.edu/module/acidbase.html+functional+groups+electron+cloud+aromatic&hl=en&ct=clnk&cd=5&gl=us from which the following material has been adapted) Related phenomena of these processes can provide an avenue for functional group affect on the π-cloud.

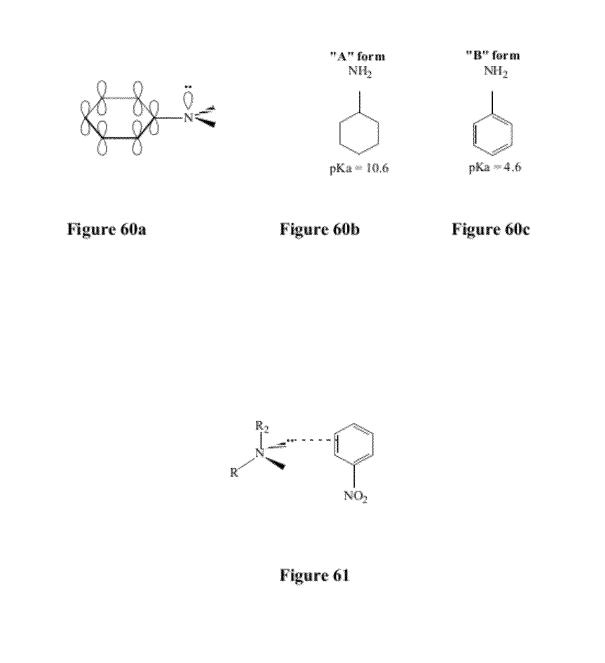

The nitrogen heteroatom in aniline is modeled as having an sp³ configuration which allows the lone pair of electrons to interact with the π-cloud as shown in FIG. 60a. This effect stabilizes the “B” form of aniline, shown in FIG. 60c, among other things leading it to be less basic than the aliphatic counterpart, cyclohexylamine (pKa 10.6) shown in FIG. 60b. This provides an avenue for functional group affect on the π-cloud.

Similarly, the nitrogen heteroatom of pyridine is modeled as having an sp² orientation, and the nitrogen orbitals are as a result planar. The lone pair is thus in the σ-bond plane of the ring and extends out of the ring making it available for bonding. Additionally, the lone pair is also pulled in by π-cloud, allowing a more attenuated avenue for functional group affect on the π-cloud.

Imide functional groups comprise nitrogen flanked by (alpha) carbonyls. The carbonyls stabilize the resonance resulting in a negative charge being distributed over five atoms. This allows imides to act as weak organic acids, and also provides an avenue for functional group affect on the π-cloud.

In charge transfer complexes, a lone pair of electrons is “shared” with a neighboring group that has significant enough π-cloud properties. (see for example http://209.85.173.132/search?g=cache:73HyNcTcgWEJ:wiz2.pharm.wayne.edu/module/acidbase.html+functional+groups+electron+cloud+aromatic&hl=en&ct=clnk&cd=5&gl=us from which the following material has been adapted). FIG. 61 depicts and example charge transfer complex.

### 9. π-π Interactions

The invention provides for electric field, magnetic field, and/or optical interaction among π-clouds of ring and fused-ring molecules that are stacked, staggered, etc. For example, in an aspect of the invention, electric field, magnetic field, and/or optical coupling is used in conjunction with a cyclophane structure. In another aspect of the invention, stacked-ring aromaticity is employed as a component in a fused-ring ring current molecular electronics system. In another aspect of the invention, π-cloud interactions involving aromatic sections of fused-ring molecules are employed as a component in a fused-ring ring current molecular electronics system.

### 10. Signal Output Aspects of the Invention

In an embodiment, a ring current within a fused-ring molecule affects a photonic phenomena signal output process.

In an embodiment, a ring current within a fused-ring molecule affects an optical property which may be used as part of a signal output process.

In an embodiment, a ring current within a fused-ring molecule affects an electrical phenomena signal output process.

In an embodiment, a ring current within a fused-ring molecule affects an electrical property which may be used as part of a signal output process.

In an embodiment, a ring current within a fused-ring molecule affects a chemical phenomena signal output process.

In an embodiment, a ring current within a fused-ring molecule affects an chemical property which may be used as part of a signal output process.

In an embodiment, a ring current within a fused-ring molecule affects a magnetic phenomena signal output process.

In an embodiment, a ring current within a fused-ring molecule affects an magnetic property which may be used as part of a signal output process.

### 11. Signal Processing Aspects of the Invention

In another aspect of the invention, a fused-ring molecule can perform a signal processing operation such as (but not limited to) amplification, threshold detection, comparator functions, nonlinear operations, hysteresis, etc.

In an embodiment, a polymer of fused-ring compounds act together to approximate a distributed-parameter component.

In an embodiment, a polymer of fused-ring compounds act together to approximate a passive distributed-parameter component.

In an embodiment, a polymer of fused-ring compounds act together to approximate an active distributed-parameter component.

In another aspect of the invention, quantum phenomena associated with a fused-ring molecule may be utilized as part of the signal processing operation performed by a fused-ring molecule.

### 12. Logic Operation Aspects of the Invention

In another aspect of the invention, a fused-ring molecule can perform a Boolean logic-gate operation such as (but not limited to) AND, OR, INVERT, NAND, NOR, etc.

In another aspect of the invention, a fused-ring molecule can perform a memory function. [11] [14] [15]

In another aspect of the invention, quantum phenomena associated with a fused-ring molecule may be utilized as part of the digital logic operation performed by a fused-ring molecule.

In another aspect of the invention, ring currents are used to provide access to quantum phenomena that can be used to access types of quantum logic processes.

In another aspect of the invention, traditional Boolean logic is combined with quantum logic.

### 13. Memory Operation Aspects of the Invention

In an aspect of the invention, a fused-ring molecule can include a data memory function. This can be accomplished in a number of possible ways, including:
The use photochromic compounds as memory elements within fused-ring molecular electronic systems that support or influence molecular ring currents, for example using the changes in topological features described earlier;
chemical induced molecular rearrangements that influences ring-currents in a fused-ring molecule, for example using the changes in topological features described earlier

### 14. Chemical Reaction Aspects of the Invention

In an aspect of the invention, molecular electronics is combined with one or more of photochemistry, molecular rearrangement chemistry, chromophore chemistry, and/or host-guest-chemistry.

### 15. Fabrication Aspects of the Invention

The fused ring-molecules and structures employing them can be fabricated by chemical systems and/or molecular assembly techniques. For example:
A desired arrangement of a plurality of fused-ring molecules can fabricated by polymerization;
A desired arrangement of a plurality of fused-ring molecules can fabricated through the use of self-assembled monolayers. [16]
A desired arrangement of a plurality of fused-ring molecules can be fabricated through the use of molecular recognition assembly.
A desired arrangement of a plurality of fused-ring molecules can be fabricated through the use of DNA-driven assembly.

While the invention has been described in detail with reference to disclosed embodiments, various modifications within the scope of the invention will be apparent to those of ordinary skill in this technological field. It is to be appreciated that features described with respect to one embodiment typically can be applied to other embodiments.

The invention can be embodied in other specific forms without departing from the spirit or essential characteristics thereof. The present embodiments are therefore to be considered in all respects as illustrative and not restrictive, the scope of the invention being indicated by the appended claims rather than by the foregoing description, and all changes which come within the meaning and range of equivalency of the claims are therefore intended to be embraced therein. Therefore, the invention properly is to be construed with reference to the claims.

### REFERENCES

[1] Kerber, Robert C. “If It's Resonance, What is Resonating?” Journal of Chemical Education 83 (2), 2006, pp. 223-227.
[2] Fliegl, H.; Sundholm, D.; Taubert, S.; Jusélius, J.; Klopper, W.; “Magnetically Induced Current Densities in Aromatic, Antiaromatic, Homoaromatic, and Nonaromatic Hydrocarbons,” J. Phys. Chem. A., 2009 Jul. 30; 113(30), pp. 8668-76.
[3] Paxtona, A.; Todorovb, T; Elena, A., “Ring Currents in Azulene,” Chemical Physics Letters, vol. 483, Issues 1-3, 24 Nov. 2009, Pages 154-158.
[4] Chandrasekhar, J.; Jemmis, E. D.; von Ragué Schleyer, P., “Double Aromaticity: Aromaticity in Orthogonal Planes. The 3,5-Dehydrophenyl Cation,” Tetrahedron Letters, Vol. 20, Issue 39, 1979, pp. 3707-3710.
[5] Barth, I.; Manz, J.; Shigeta, Y.; Yagi, K, “Unidirectional Electronic Ring Current Driven by a Few Cycle Circularly Polarized Laser Pulse: Quantum Model Simulations for Mg-Porphyrin,” J. Am. Chem. Soc., 2006, 128 (21), pp. 7043-7049.
[6] Barth, I., Quantum Control of Electron and Nuclear Circulations, Ring Currents, and Induced Magnetic Fields in Atoms, Ions, and Molecules by Circularly Polarized Laser Pulses,” Dissertation, Freien Universitat Berlin, 2009.
[7] Nobusadaa, K.; Yabana, K., “Electric currents in ring-shaped molecules induced by circularly polarized laser pulses,” Computer Physics Communications, vol. 177, Issues 1-2, July 2007, Page 54.
[8] Fowler, P.; Havenith, R.; Soncini, A.; Steiner, E., “Paratropic Delocalized Ring Currents in Flattened Cyclooctatetraene Systems with Bond Alternation,” Angewandte Chemie International Edition, vol. 41, Issue 9, pages 1558-1560, May 3, 2002.
[9] Averkiev, B. B., “Hf3 Cluster Is Triply (π-, π-, and δ-) Aromatic in the Lowest D₃ₕ, ¹A₁′ State,” Tetrahedron Letters, Vol. 20, Issue 39, 1979, pp. 3707-3710.
[10] Cheney, V. B., Magnetic Deshielding of Protons due to Intramolecular Steric Interactions with Proximate Hydrogens, J. Am. Chem. Soc., 1968, 90 (20), pp 5386-5390.
[11] Matsuda, K.; Irie, M., “Photoswitching of Intramolecular Magnetic Interaction Using Photochromic Compounds” in Chemistry of Nanomolecular Systems, T. Nakamura et al., pp. 25-40.
[12] Aihara, J., “Graph-Theoretical Formula for Ring Currents Induced in a Polycyclic Conjugated System,” Bull. Chem. Soc. Jpn., 56, June, 1983, pp. 1853-1854. (See minor correction in the formula in Reference 3 in Aihara, J., “General Formulas for Evaluating Ring Currents Induced in a Polycyclic Conjugated System,” Bull. Chem. Soc. Jpn., 58, March 1985, pp. 1045-1046,)
[13] Gosmann, M.; Franck, B., “Synthesis of a Fourfold Enlarged Porphyrin with an Extremely Large, Diamagnetic Ring-Current Effect,” Angewandte Chemie International Edition in English, Vol. 25, Issue 12, pp. 1100-1101, December 1986.
[14] T. Suzuki et al “Dynamic Redox Systems: Towards the Realization of Unimolecular Memory” in Chemistry of Nanomolecular Systems, T. Nakamura et al., pp. 3-24.
[15] Takeda, K.; et al., “Single Molecule Magnets” in Chemistry of Nanomolecular Systems, T. Nakamura et al., pp. 41-57.
[16] Ishida, T., “Self-Assembled Monolayers for Molecular Electronics” in Chemistry of Nanomolecular Systems, T. Nakamura et al., pp. 91-106.

I claim:

1. A system implementing molecular electronics, the system comprising:
a molecule comprising a fused-ring cyclic structure and a molecular orbital structure capable of supporting a plurality of ring currents;
at least one topological feature of the molecule that can be changed by an input stimulus;
at least one topological feature of the molecule that can be changed by an associated input stimulus; and
at least one aspect of the ring currents that induces an associated output effect responsive to changes in the ring currents,
wherein at least one ring current is induced by at least one time-varying magnetic field, and
wherein the mutual interaction among ring currents in a fused ring molecule is used to create the electron flows of a mesh-topology electrical circuit.

2. The system of claim 1 wherein the molecule comprises a photochromic component.

3. The system of claim 1 wherein the molecule comprises a pH indicator component.

4. The system of claim 1 wherein the input stimulus comprises a photon.

5. The system of claim 4 wherein the absorbed photon causes a photo-induced molecular rearrangement.

6. The system of claim 4 wherein a ring current within the molecule is turned on and off by photo-induced molecular rearrangement.

7. The system of claim 1 wherein the input stimulus comprises a chemical stimulus.

8. The system of claim 1 wherein the input stimulus comprises a pH change.

9. The system of claim 1 wherein the molecule comprises a pi-electron cloud.

10. The system of claim 1 wherein the molecule comprises an extended pi-orbital.

11. The system of claim 1 wherein the molecule comprises a conjugated pi-system.

12. The system of claim 1 wherein ring currents are induced by a circularly polarized laser pulse.

13. The system of claim 1 wherein the molecule further comprises a bridge.

14. The system of claim 1 wherein ring currents are induced by at least two spatially-orthogonal time-varying magnetic fields.

15. The system of claim 1 wherein at least one time-varying magnetic field is employed as a power source to induce the ring current.

16. The system of claim 1 wherein at least one ring current flows within an essentially geometric plane essentially parallel to an essentially geometric plane defined by the location of the atom members of a ring of bonds.

17. The system of claim 1 wherein changes in one ring current cause changes in another ring current.

18. The system of claim 16 wherein changes in one ring current occurs in a plane differing from the plane of another ring current.

19. The system of claim 1 wherein a ring current is externally measured.

20. The system of claim 1 wherein the molecule comprises molecular strain.
